(19) United States
(12) Patent Application Publication
(10) Pub. No.: US 2024/0196689 A1
(43) Pub. Date: Jun. 13, 2024

(54) DISPLAY PANEL, DISPLAY MODULE, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Bangqing XIAO, Beijing (CN); Benlian WANG, Beijing (CN); Zhengkun LI, Beijing (CN); Hai ZHENG, Beijing (CN)

(21) Appl. No.: 18/554,961

(22) PCT Filed: Jan. 29, 2023
(86) PCT No.: PCT/CN2023/073704

§ 371 Date: Oct. 11, 2023

(30) Foreign Application Priority Data
Jan. 30, 2022 (WO) PCT/CN2022/075193
Sep. 28, 2022 (CN) 202211193942.7

(51) Int. Cl. H10K 59/35; H10K 59/122; H10K 59/131; H10K 59/65

(52) U.S. Cl. CPC H10K 59/353; H10K 59/122; H10K 59/131; H10K 59/65

(57) ABSTRACT

Provided is a display panel. The display panel includes: a base substrate, including a first display region and a second display region at least partially surrounding the first display region; a drive circuit layer on a side of the base substrate, wherein the drive circuit layer includes a plurality of first pixel circuits and a plurality of second pixel circuits that are disposed in the second display region; and a first electrode layer, at least including a plurality of first-type electrode patterns, wherein the plurality of first-type electrode patterns include a plurality of first electrode patterns in the first display region and a plurality of second electrode patterns in the second display region; wherein at least two first electrode patterns are connected to the first pixel circuit, and at least two second electrode patterns are connected to the second pixel circuit.

### CROSS-REFERENCE TO RELATED APPLICATION

This application is a U.S. national stage of international application No. PCT/CN2023/073704, filed on Jan. 29, 2023, which claims priorities to PCT international Patent Application No. PCT/CN2022/075193 filed on Jan. 30, 2022, and entitled “DISPLAY PANEL AND MANUFACTURING METHOD THEREFOR, AND DISPLAY DEVICE” and Chinese Patent Application No. 202211193942.7 filed on Sep. 28, 2022, and entitled “DISPLAY PANEL, DISPLAY MODULE AND DISPLAY DEVICE,” and the disclosures of which are herein incorporated by references in their entireties.

### TECHNICAL FIELD

The present disclosure relates to the field of display technologies, and in particular, relates to a display panel, a display module, and a display device.

### BACKGROUND

Organic light-emitting diode (OLED) display panels are widely used due to self-luminescence, low driving voltages, and fast response. Generally, the OLED display panel includes a plurality of pixel units, and each of the plurality of pixel units includes a light-emitting device and a pixel circuit connected to the light-emitting device.

### SUMMARY

Embodiments of the present disclosure provide a display panel, a display module, and a display device. The technical solutions are as follows.

In some embodiments of the present disclosure, a display panel is provided. The display panel includes:
a base substrate, including a first display region and a second display region at least partially surrounding the first display region;
a drive circuit layer on a side of the base substrate, wherein the drive circuit layer includes a plurality of first pixel circuits and a plurality of second pixel circuits that are disposed in the second display region; and
a first electrode layer, at least including a plurality of first-type electrode patterns, wherein the plurality of first-type electrode patterns include a plurality of first electrode patterns in the first display region and a plurality of second electrode patterns in the second display region;
wherein at least two of the plurality of first electrode patterns are connected to one of the plurality of first pixel circuits, and at least two of the plurality of second electrode patterns are connected to one of the plurality of second pixel circuits.

In some embodiments, the display panel further includes:
a plurality of first connection traces in the first display region;
a plurality of second connection traces extending from the second display region to the first display region along a pixel row direction;
a plurality of third connection traces in the second display region;
wherein at least two of the plurality of first electrode patterns are connected via one of the plurality of first connection traces, one of the at least two of the plurality of first electrode patterns is connected to the one of the plurality of first pixel circuits via one of the plurality of second connection traces, at least two of the plurality of second electrode patterns are connected via one of the plurality of third connection traces, and one of the at least two of the plurality of second electrode patterns is connected to the one of the plurality of second pixel circuits.

In some embodiments, the display panel further includes: a plurality of fourth connection traces and a plurality of fifth connection traces that extend from the second display region to the first display region along the pixel row direction, and the first electrode layer further includes a plurality of second-type electrode patterns and a plurality of third-type electrode patterns; wherein
the plurality of second-type electrode patterns include a plurality of third electrode patterns in the first display region and a plurality of fourth electrode patterns in the second display region, wherein each of the plurality of third electrode patterns is connected to the one of the plurality of first pixel circuits via one of the plurality of fourth connection traces; and
the plurality of third-type electrode patterns include a plurality of fifth electrode patterns in the first display region and a plurality of sixth electrode patterns in the second display region, wherein each of the plurality of fifth electrode patterns is connected to the one of the plurality of first pixel circuits via one of the plurality of fifth connection traces.

In some embodiments, two of the plurality of first pixel circuits and three of the plurality of second pixel circuits that are adjacent form a circuit set, at least two of the plurality of second electrode patterns form an electrode pattern set, and one of the electrode pattern sets, one of the plurality of fourth electrode patterns, and one of the plurality of sixth electrode patterns that are adjacent form a pattern set,
wherein each of the pattern sets corresponds to one of the circuit sets, and for the each of the pattern sets and the corresponding circuit set, an orthogonal projection of the each of the pattern sets on the base substrate is overlapped with an orthogonal projection of the corresponding circuit set on the base substrate.

In some embodiments, for each of the circuit sets and the pattern set corresponding to the each of the circuit sets, in three of the plurality of second pixel circuits in the each of the circuit sets, a first second pixel circuit in the three second pixel circuits is connected to one of the plurality of second electrode patterns in the electrode pattern set in the one pattern set, a second second pixel circuit in the three second pixel circuits is connected to the one of the fourth electrode pattern in the one pattern set, and a third second pixel circuit in the three second pixel circuits is connected to the sixth electrode pattern in the one pattern set.

In some embodiments, two of the plurality of first pixel circuits in one part of circuit sets in the display panel are connected to electrode patterns in the first display region, and two of the plurality of first pixel circuits in the other part of the circuit sets in the display panel are connected to a fixed voltage terminal.

In some embodiments, the one part of circuit sets of the two of the plurality of first pixel circuits connected to the electrode patterns in the first display region are closer to the first display region than the other part of the circuit sets of the two of the plurality of first pixel circuits connected to the fixed voltage terminal are.

In some embodiments, the display panel further includes: red sub-pixels, green sub-pixels, and blue sub-pixels, wherein sub-pixels of the plurality of first-type electrode patterns are the green sub-pixels, sub-pixels of the plurality of second-type electrode patterns are the red sub-pixels, and sub-pixels of the plurality of third-type electrode patterns are the blue sub-pixels.

In some embodiments, a length of any of the plurality of second connection traces along the pixel row direction is less than a length of each of the plurality of fourth connection traces along the pixel row direction and a length of each of the plurality of fifth connection traces along the pixel row direction.

In some embodiments, for each connection trace in the plurality of second connection traces, the plurality of fourth connection traces, and the plurality of fifth connection traces, a length of the each connection trace along the pixel row direction is positively correlated with a distance between the electrode pattern in the first display region connected to the each connection trace and the second display region along the pixel row direction.

In some embodiments, the second display region includes a first display sub-region, a second display sub-region, and a third display sub-region, wherein the first display sub-region and the first display region are arranged in a pixel column direction, the second display sub-region and the first display region are arranged along the pixel row direction, the third display sub-region and the first display sub-region are arranged along the pixel row direction, and the third display sub-region and the second display sub-region are arranged in the pixel column direction; and
the display panel further includes a plurality of first data lines in the first display sub-region, a plurality of second data lines in the second display sub-region and the third display sub-region, a plurality of first patch codes in the first display sub-region and the third display sub-region, wherein
the plurality of first data lines are arranged along the pixel row direction and extend in the pixel column direction, the plurality of second data lines are arranged along the pixel row direction and extend in the pixel column direction, and the plurality of first patch codes are arranged in the pixel column direction and extend along the pixel row direction; a first end of each of the plurality of first data lines is configured to be connected to a data drive circuit, a second end of the each of the plurality of first data lines is connected to a first end of one of the plurality of first patch codes, a second end of each of the plurality of first patch codes is connected to a first end of one of the plurality of second data lines; and the each of the plurality of first data lines is further connected to one column of the second pixel circuits configured to be connected to first target electrode patterns in the first display sub-region, and each of the plurality of second data lines is further connected to one column of the first pixel circuits configured to be connected to second target electrode patterns in the second display sub-region; wherein the first target electrode patterns are at least one of the plurality of fourth electrode patterns and the plurality of sixth electrode patterns, and the second target electrode patterns are at least one of the plurality of third electrode patterns and the plurality of fifth electrode patterns.

In some embodiments, the first target electrode patterns are the plurality of fourth electrode patterns or the plurality of sixth electrode patterns, the second target electrode patterns are the plurality of third electrode patterns or the plurality of fifth electrode patterns, and the display panel further includes a plurality of third data lines in the first display sub-region, and a plurality of fourth data lines in the second display sub-region and the third display sub-region; wherein
the plurality of third data lines are arranged along the pixel row direction and extend in the pixel column direction, a first end of each of the plurality of third data lines is configured to be connected to the data drive circuit, and the each of the plurality of third data lines is further connected to one column of the second pixel circuits configured to be connected to the plurality of second electrode patterns in the first display sub-region; and
the plurality of fourth data lines are arranged along the pixel row direction and extend in the pixel column direction, a first end of each of the plurality of fourth data lines is configured to be connected to the data drive circuit, and the each of the plurality of fourth data lines is further connected to one column of the first pixel circuits configured to be connected to the plurality of first electrode patterns in the second display sub-region.

In some embodiments, the second display region further includes a fourth display sub-region and a fifth display sub-region, wherein the fourth display sub-region is disposed on a side, distal from the first display sub-region, of the first display region, the fifth display sub-region and the fourth display sub-region are arranged along the pixel row direction, and the plurality of second data lines are disposed in the fifth display sub-region; and
the display panel further includes a plurality of second patch codes and a plurality of fifth data lines in the fourth display sub-region, wherein the plurality of fifth data lines are arranged along the pixel row direction and extend in the pixel column direction, and the plurality of second patch codes are arranged in the pixel column direction and extend along the pixel row direction; a second end of the each of the plurality of second data lines is connected to a first end of one of the plurality of second patch codes, a second end of each of the plurality of second patch codes is connected to a first end of each of the plurality of fifth data lines, and each of the plurality of fifth data lines is further connected to one column of the second pixel circuits configured to be connected to the first target electrode patterns in the fourth display sub-region.

In some embodiments, the display panel further includes: a plurality of first dummy data lines in the third display sub-region, wherein the plurality of first dummy data lines are arranged along the pixel row direction and extend in the pixel column direction, configured to be connected to a fixed voltage terminal, and further connected to one column of the first pixel circuits in the third display sub-region.

In some embodiments, the second display region further includes a sixth display sub-region on a side, distal from the first display sub-region, of the third display sub-region; and
the display panel further includes a plurality of seventh data lines in the sixth display sub-region and a plurality of second dummy data lines in the sixth display sub-region; wherein
the plurality of seventh data lines are arranged along the pixel row direction and extend in the pixel column direction, and each of the plurality of seventh data lines is configured to be connected to a data drive circuit and further connected to one column of the second pixel circuits in the sixth display sub-region; and
the plurality of second dummy data lines are arranged along the pixel row direction and extend in the pixel column direction, each of the plurality of second dummy data lines is configured to be connected to a fixed voltage terminal, and the plurality of second dummy data lines are further connected to one column of the first pixel circuits in the sixth display sub-region.

In some embodiments, the plurality of third connection traces and the first electrode layer are disposed in a same layer, and the plurality of first connection traces and the plurality of second connection traces are disposed between the drive circuit layer and the first electrode layer.

In some embodiments of the present disclosure, a display module is provided. The display module includes a data drive circuit and the display panel in the above embodiments;
wherein the data drive circuit is connected to first data lines, third data lines, fourth data lines, and seventh data lines that are in the display panel.

In some embodiments of the present disclosure, a display device is provided. The display device includes the display module in the above embodiments and an optical sensor, wherein an orthogonal projection of the optical sensor on the display panel is at least partially overlapped with a first display region in the display panel.

### BRIEF DESCRIPTION OF DRAWINGS

For clearer description of the technical solutions in the embodiments of the present disclosure, the following briefly describes the accompanying drawings required for describing the embodiments. Apparently, the accompanying drawings in the following description show merely some embodiments of the present disclosure, and those of ordinary skill in the art may still derive other drawings from these accompanying drawings without any creative efforts.

FIG. 1 is a locally structural diagram of a display panel according to some embodiments of the present disclosure;

FIG. 2 is a locally enlarged diagram of the display panel shown in FIG. 1;

FIG. 3 is a top view of a base substrate according to some embodiments of the present disclosure;

FIG. 4 is a locally section view of a display panel according to some embodiments of the present disclosure;

FIG. 5 is a locally schematic diagram of a first electrode layer in a second display region according to some embodiments of the present disclosure;

FIG. 6 is a locally schematic diagram of a first electrode layer in a first display region according to some embodiments of the present disclosure;

FIG. 7 is a locally schematic diagram of first pattern rows in a first display region according to some embodiments of the present disclosure;

FIG. 8 is a locally structural diagram of another display panel according to some embodiments of the present disclosure;

FIG. 9 is a locally enlarged diagram of the display panel shown in FIG. 8;

FIG. 10 is a schematic diagram of data liens, patch codes, and dummy data liens in a display panel according to some embodiments of the present disclosure;

FIG. 11 is another schematic diagram of data liens, patch codes, and dummy data liens in a display panel according to some embodiments of the present disclosure;

FIG. 12 is a schematic diagram of a display panel without a first pixel circuit according to some embodiments of the present disclosure;

FIG. 13 is a schematic diagram of a design of another one pixel circuit for two pixel circuits according to some embodiments of the present disclosure;

FIG. 14 is a schematic diagram of a circuit set according to some embodiments of the present disclosure;

FIG. 15 is a schematic diagram of another circuit set according to some embodiments of the present disclosure;

FIG. 16 is an equivalent circuit diagram of a first pixel circuit or a second pixel circuit according to some embodiments of the present disclosure;

FIG. 17 is a locally schematic diagram of a semiconductor layer in a display panel according to some embodiments of the present disclosure;

FIG. 18 is a locally schematic diagram of a first gate layer in a display panel according to some embodiments of the present disclosure;

FIG. 19 is a locally schematic diagram of superposition of a semiconductor layer and a first gate layer in a display panel according to some embodiments of the present disclosure;

FIG. 20 is a locally schematic diagram of a second gate layer in a display panel according to some embodiments of the present disclosure;

FIG. 21 is a locally schematic diagram of superposition of a semiconductor layer, a first gate layer, and a second gate layer in a display panel according to some embodiments of the present disclosure;

FIG. 22 is a locally schematic diagram of an interlayer dielectric layer in a display panel according to some embodiments of the present disclosure;

FIG. 23 is a locally schematic diagram of superposition of a semiconductor layer, a first gate layer, a second gate layer, and an interlayer dielectric layer in a display panel according to some embodiments of the present disclosure;

FIG. 24 is a locally schematic diagram of a first source and drain layer in a display panel according to some embodiments of the present disclosure;

FIG. 25 is a locally schematic diagram of superposition of a semiconductor layer, a first gate layer, a second gate layer, an interlayer dielectric layer, and a first source and drain layer in a display panel according to some embodiments of the present disclosure;

FIG. 26 is a locally schematic diagram of a passivation layer in a display panel according to some embodiments of the present disclosure;

FIG. 27 is a locally schematic diagram of superposition of a semiconductor layer, a first gate layer, a second gate layer, an interlayer dielectric layer, a first source and drain layer, and a passivation layer in a display panel according to some embodiments of the present disclosure;

FIG. 28 is a locally schematic diagram of an intermediate source and drain layer in a display panel according to some embodiments of the present disclosure;

FIG. 29 is a locally schematic diagram of superposition of a semiconductor layer, a first gate layer, a second gate layer, an interlayer dielectric layer, a first source and drain layer, a passivation layer, and an intermediate source and drain layer in a display panel according to some embodiments of the present disclosure;

FIG. 30 is a locally schematic diagram of a first planarization layer in a display panel according to some embodiments of the present disclosure;

FIG. 31 is a locally schematic diagram of superposition of a semiconductor layer, a first gate layer, a second gate layer, an interlayer dielectric layer, a first source and drain layer, a passivation layer, an intermediate source and drain layer, and a first planarization layer in a display panel according to some embodiments of the present disclosure;

FIG. 32 is a locally schematic diagram of a second source and drain layer in a display panel according to some embodiments of the present disclosure;

FIG. 33 is a locally schematic diagram of superposition of a semiconductor layer, a first gate layer, a second gate layer, an interlayer dielectric layer, a first source and drain layer, a passivation layer, an intermediate source and drain layer, a first planarization layer, and a second source and drain layer in a display panel according to some embodiments of the present disclosure;

FIG. 34 is a locally schematic diagram of a second planarization layer in a display panel according to some embodiments of the present disclosure;

FIG. 35 is a locally schematic diagram of superposition of a semiconductor layer, a first gate layer, a second gate layer, an interlayer dielectric layer, a first source and drain layer, a passivation layer, an intermediate source and drain layer, a first planarization layer, a second source and drain layer, and a second planarization layer in a display panel according to some embodiments of the present disclosure;

FIG. 36 is a flowchart of a method for manufacturing a display panel according to some embodiments of the present disclosure;

FIG. 37 is a locally schematic diagram of a first conduction layer in a display panel according to some embodiments of the present disclosure;

FIG. 38 is a locally schematic diagram of superposition of formation of a first conduction layer in a display panel according to some embodiments of the present disclosure;

FIG. 39 is a locally schematic diagram of a first insulative layer in a display panel according to some embodiments of the present disclosure;

FIG. 40 is a locally schematic diagram of superposition of formation of a first insulative layer in a display panel according to some embodiments of the present disclosure;

FIG. 41 is a locally schematic diagram of a second conduction layer in a display panel according to some embodiments of the present disclosure;

FIG. 42 is a locally schematic diagram of superposition of formation of a second conduction layer in a display panel according to some embodiments of the present disclosure;

FIG. 43 is a locally schematic diagram of a second insulative layer in a display panel according to some embodiments of the present disclosure;

FIG. 44 is a locally schematic diagram of superposition of formation of a second insulative layer in a display panel according to some embodiments of the present disclosure;

FIG. 45 is a locally schematic diagram of a third conduction layer in a display panel according to some embodiments of the present disclosure;

FIG. 46 is a locally schematic diagram of superposition of formation of a third conduction layer in a display panel according to some embodiments of the present disclosure;

FIG. 47 is a locally schematic diagram of a third insulative layer in a display panel according to some embodiments of the present disclosure;

FIG. 48 is a locally schematic diagram of superposition of formation of a third insulative layer in a display panel according to some embodiments of the present disclosure;

FIG. 49 is a locally schematic diagram of a first electrode layer in a display panel according to some embodiments of the present disclosure;

FIG. 50 is a locally schematic diagram of superposition of formation of a first electrode layer in a display panel according to some embodiments of the present disclosure;

FIG. 51 is a locally schematic diagram of a pixel definition layer in a display panel according to some embodiments of the present disclosure;

FIG. 52 is a locally schematic diagram of superposition of formation of a pixel definition layer in a display panel according to some embodiments of the present disclosure;

FIG. 53 is a locally schematic diagram of a conduction layer in a display panel according to some embodiments of the present disclosure;

FIG. 54 is a schematic structural diagram of a display module according to some embodiments of the present disclosure; and

FIG. 55 is a schematic structural diagram of a display device according to some embodiments of the present disclosure.

### DETAILED DESCRIPTION

To make the objectives, technical solutions, and advantages of the present disclosure clearer, the embodiments of the present disclosure are further described in detail hereinafter with reference to the accompanying drawings.

In some practices, for improvement of a screen-to-body ratio of a display panel, a camera of a display device is disposed in a display region of the display panel. In addition, for improvement of a transmittance of a region of the camera, pixel circuits of pixel units in the region of the camera (that is, a camera region) are disposed in a non-camera region. The pixel circuits in the non-camera region are connected to light-emitting elements in the camera region via connection traces, such that a drive signal is supplied to the light-emitting elements in the camera region to drive the light-emitting elements to emit light.

However, as the pixel circuits connected to the light-emitting elements in the camera region require to be disposed in the non-camera region, pixel circuits in the non-camera region are great, such that a space of each pixel circuit is less, and the processes are difficult.

Embodiments of the present disclosure provide a display panel. For example, the display panel is an organic light-emitting diode (OLED) display panel, a micro organic light-emitting diode (Micro OLED) display panel, a quantum dot light emitting diodes (QLED) display panel, a mini light-emitting diode (Mini LED) display panel, a micro light-emitting diode (Micro LED) display panel, and the like. The following is described by taking the display panel is the OLED display panel as an example.

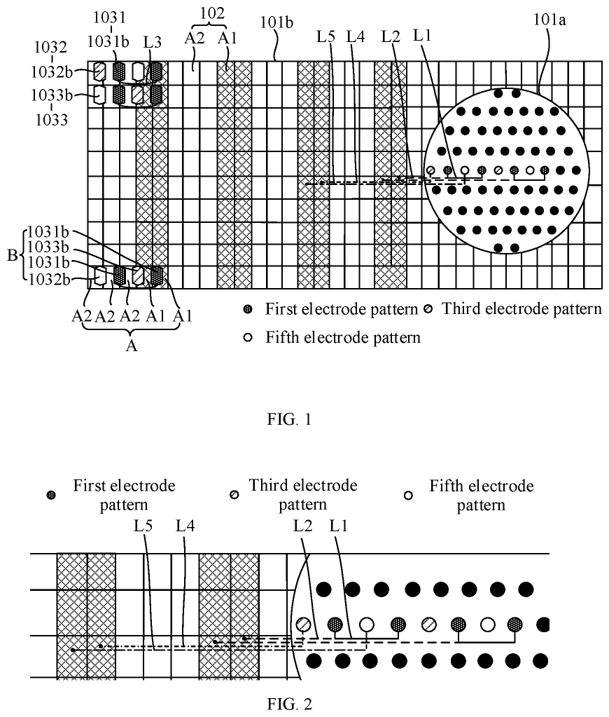

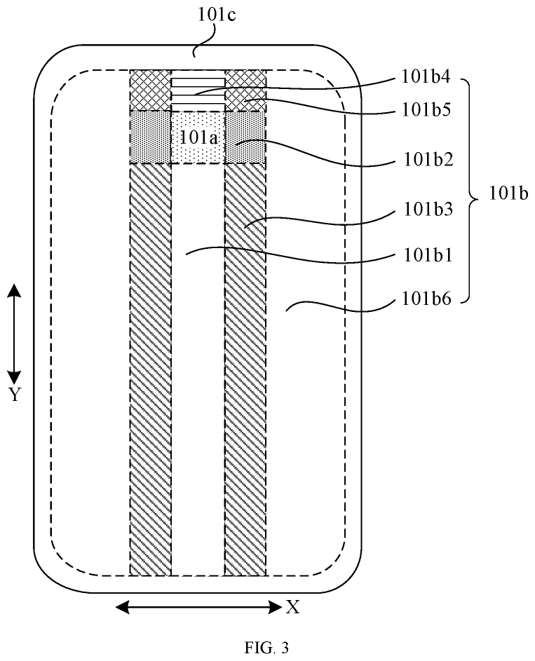

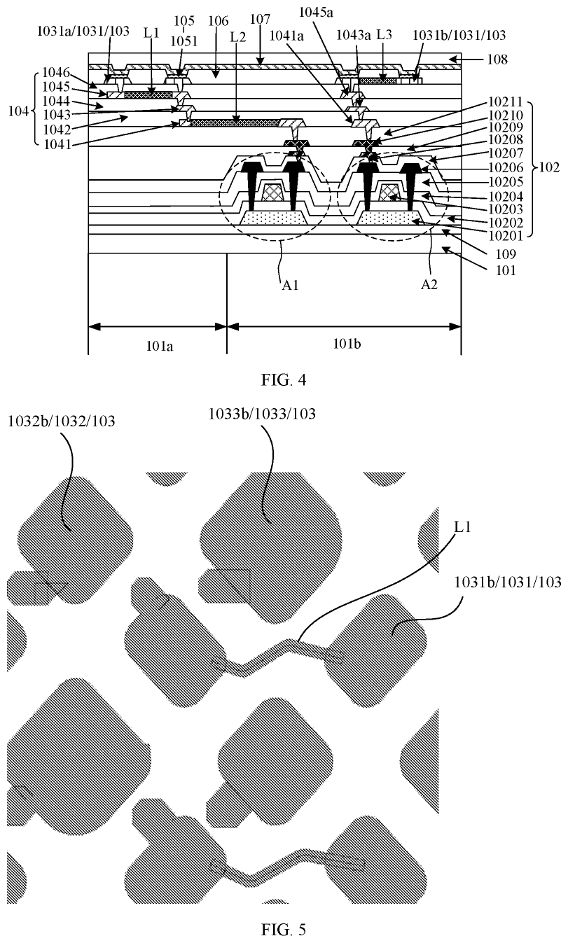

FIG. 1 is a locally structural diagram of a display panel according to some embodiments of the present disclosure. FIG. 2 is a locally enlarged diagram of the display panel shown in FIG. 1. FIG. 3 is a top view of a base substrate according to some embodiments of the present disclosure. FIG. 4 is a locally section view of a display panel according to some embodiments of the present disclosure. In conjunction with FIG. 1 to FIG. 4, the display panel 10 includes a base substrate 101, a drive circuit layer 102 on a side of the base substrate 101, and a first electrode layer 103.

The base substrate 101 includes a first display region 101a and a second display region 101b at least partially surrounding the first display region 101a. The first display region 101a is a full display with camera (FDC) region, and is a circular region or a rectangular region.

The drive circuit layer 102 includes a plurality of first pixel circuits A1 and a plurality of second pixel circuits A2 that are disposed in the second display region 101b. FIG. 3 shows one first pixel circuit A1 and one second pixel circuit A2.

The first electrode layer 103 at least includes a plurality of first-type electrode patterns 1031. The plurality of first-type electrode patterns 1031 include a plurality of first electrode patterns 1031a in the first display region 101a and a plurality of second electrode patterns 1031b in the second display region 101b. The display panel 10 includes a plurality of sub-pixels of different colors, and each sub-pixel a light-emitting device and a pixel circuit for controlling the light-emitting device to emit light. Luminance (grayscales) of sub-pixels of different colors is adjusted by the pixel circuits, and display of various colors is achieved by combining and superposing colors, such that colorful display of the display panel 10 is achieved. The light-emitting device includes one electrode pattern. Colors of light from the sub-pixels of the plurality of first-type electrode patterns 1031 are the same.

At least two first electrode patterns 1031a are connected to one first pixel circuit A1, such that the one first pixel circuit A1 supplies a data drive signal to the two first electrode patterns 1031a. At least two second electrode patterns 1031b are connected to one second pixel circuit A2, such that the one second pixel circuit A2 supplies a data drive signal to the two second electrode patterns 1031b.

In the embodiments of the present disclosure, at least two first electrode patterns 1031a in the first display region 101a are driven by one first pixel circuit A1 in the second display region 101b, and at least two second electrode patterns 1031b in the second display region 101b are driven by one second pixel circuit A2 in the second display region 101b. Thus, in the case that numbers of electrode patterns are the same, compared with driving one electrode pattern by one pixel circuit, a number of pixel circuits in the second display region 101b is reduced in driving two electrode patterns by one pixel circuit, such that a space of each pixel circuit is increased, and the process difficulty is less.

In summary, the embodiments of the present disclosure provide a display panel. As at least two first electrode patterns in the display panel are connected, and one of the at least two connected first electrode patterns is connected to one first pixel circuit, the one first pixel circuit drives the two first electrode patterns. As at least two second electrode patterns are connected, and one of the at least two connected second electrode patterns is connected to one second pixel circuit, the one second pixel circuit drives the two second electrode patterns. Thus, in the case that numbers of electrode patterns are the same, a number of pixel circuits in the second display region is reduced in driving two electrode patterns by one pixel circuit, such that a space of each pixel circuit is increased, and the process difficulty is less.

In some embodiments, the transmissivity of the base substrate 101 and the transmissivity of the portion of the drive circuit layer 102 in the first display region 101a are great. Illustratively, the base substrate 101 is a transparent glass substrate with a great transmittance, and the portion of the drive circuit layer 102 in the first display region 101a is not provided with a circuit structure (that is, the first pixel circuits A1 and the second pixel circuits A2 are disposed in the second display region 101b and not disposed in the first display region 101a) to ensure an enough transmittance of the drive circuit layer 102. In the display device, a side, distal from the drive circuit layer 102, of the base substrate 101 is provided with a sensor, for example, a camera, a proximity optical sensor, a 3D sensing module, and other optical sensors. An orthogonal projection of the sensor on the base substrate 101 is within the first display region 101a. A light sensing face of the optical sensor faces towards a side of a display face of the display panel 10 and is configured to receive ambient light from the side of the display face of the display panel 10. Illustratively, the first electrode pattern 1031a in the first electrode layer 103 in the first display region 101a is made of a transparent conductive material, for example, an indium tin oxide (ITO), an indium zinc oxide (IZO), such that the transmissivity of the first display region 101a is great, and the camera and other devices with a great transmittance requirement are disposed in the first display region 101a. The optical sensor is disposed in the first display region 101a, and is capable of receiving the ambient light by running through the first display region 101a, such that corresponding functions are achieved.

Referring to FIG. 1 and FIG. 2, the display panel 10 further includes a plurality of first connection traces L1, a plurality of second connection traces L2, and a plurality of third connection traces L3. The plurality of first connection traces L1 are disposed in the first display region 101a. The plurality of second connection traces L2 extend from the second display region 101b to the first display region 101a along a pixel row direction X, and are disposed in the first display region 101a and the second display region 101b. The plurality of third connection traces L3 are disposed in the second display region 101b.

At least two first electrode patterns 1031a are connected via one first connection trace L1, and one of the at least two first electrode patterns 1031a is connected to the one first pixel circuit A1 via one second connection trace L2, such that the one first pixel circuit A1 supplies the data drive signal to the two first electrode patterns 1031a. In addition, at least two second electrode patterns 1031b are connected via one third connection trace L3, and one of the at least two second electrode patterns 1031b is connected to one second pixel circuit A2, such that the one second pixel circuit A2 supplies the data drive signal to the two second electrode patterns 1031b.

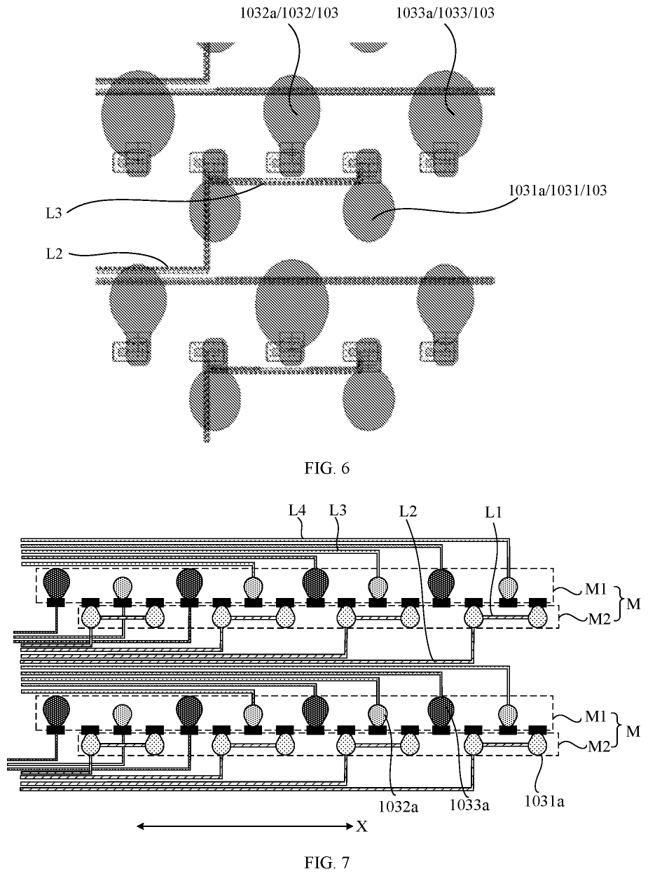

In the embodiments of the present disclosure, referring to FIG. 1 and FIG. 2, the display panel 10 further includes a plurality of fourth connection traces L4 and a plurality of fifth connection traces L5 that extend from the second display region 101b to the first display region 101a along the pixel row direction X. In conjunction with FIG. 1, FIG. 5, and FIG. 6, the first electrode layer 103 further includes a plurality of second-type electrode patterns 1032 and a plurality of third-type electrode patterns 1033. The plurality of second-type electrode patterns 1032 include a plurality of third electrode patterns 1032a in the first display region 101a and a plurality of fourth electrode patterns 1032b in the second display region 101b. The plurality of third-type electrode patterns 1033 include a plurality of fifth electrode patterns 1033a in the first display region 101a and a plurality of sixth electrode patterns 1033b in the second display region 101b.

The third electrode pattern 1032a is connected to one first pixel circuit A1 via one fourth connection trace L4, and the fourth electrode pattern 1032b is connected to one second pixel circuit A2. The fifth electrode pattern 1033a is connected to one first pixel circuit A1 via one fifth connection trace L5, and the sixth electrode pattern 1033b is connected to one second pixel circuit A2. That is, each of the plurality of third electrode patterns 1032a and the plurality of fifth electrode patterns 1033a is riven by one first pixel circuit A1, and each of the plurality of fourth electrode patterns 1032b and the plurality of sixth electrode patterns 1033b is riven by one second pixel circuit A2.

In the embodiments of the present disclosure, referring to FIG. 7, in the first display region 101a, the plurality of first electrode patterns 1031a, the plurality of third electrode patterns 1032a, and the plurality of fifth electrode patterns 1033a are arranged in a plurality of rows, and a plurality of electrode patterns in one row are referred to as a first pattern row M. At least one first pattern row M includes at least two first electrode patterns 1031a, at least one third electrode pattern 1032a, and at least one fifth electrode pattern 1033a that are arranged in one row. The at least two first electrode patterns 1031a are connected via the first connection trace L1.

In some embodiments, the first pattern row M is disposed in a repeated order of the third electrode pattern 1032a, the first electrode pattern 1031a, the fifth electrode pattern 1033a, and the first electrode pattern 1031a. Illustratively, a plurality of first pattern rows M are arranged in a plurality of rows, and each first pattern row M includes a first pattern sub-row M1 and a second pattern sub-row M2 that are disposed in parallel. The third electrode pattern 1032a and the fifth electrode pattern 1033a in the first pattern sub-row M1 are alternately disposed, and a plurality of first electrode patterns 1031a in the second pattern sub-row M2 are sequentially disposed. A number of the first electrode patterns 1031a in the second pattern sub-row M2 is coincided with a sum of a number of the third electrode patterns 1032a and a number of the fifth electrode patterns 1033a in the first pattern sub-row M1, and the first electrode pattern 1031a is disposed on a central axis line of the adjacent third electrode pattern 1032a and the fifth electrode pattern 1033a.

In addition, in the second display region 101b, the plurality of second electrode patterns 1031b, the plurality of fourth electrode patterns 1032b, and the plurality of sixth electrode patterns 1033b are arranged in a plurality of rows, and a plurality of electrode patterns in one row are referred to as a second pattern row (not shown in the drawing). At least one second pattern row includes at least two second electrode patterns 1031b, at least one fourth electrode pattern 1032b, and at least one sixth electrode pattern 1033b that are arranged in one row. The at least two second electrode patterns 1031b are connected via the third connection trace L3.

In some embodiments, the second pattern row is disposed in a repeated order of the fourth electrode pattern 1032b, the second electrode pattern 1031b, the sixth electrode pattern 1033b, and the second electrode pattern 1031b. Illustratively, a plurality of second pattern rows are arranged in a plurality of rows, and each second pattern row includes a third pattern sub-row and a fourth pattern sub-row that are disposed in parallel. The fourth electrode pattern 1032b and the sixth electrode pattern 1033b in the third pattern sub-row are alternately disposed, and a plurality of second electrode patterns 1031b in the fourth pattern sub-row are sequentially disposed. A number of the second electrode patterns 1031b in the fourth pattern sub-row is coincided with a sum of a number of the fourth electrode patterns 1032b and a number of the sixth electrode patterns 1033b in the third pattern sub-row, and the second electrode pattern 1031b is disposed on a central axis line of the adjacent fourth electrode pattern 1032b and the sixth electrode pattern 1033b.

In some embodiments, the plurality of first electrode patterns 1031a, the plurality of third electrode patterns 1032a, and the plurality of fifth electrode patterns 1033a are arranged in a plurality of columns, and the plurality of second electrode patterns 1031b, the plurality of fourth electrode patterns 1032b, and the plurality of sixth electrode patterns 1033b are arranged in a plurality of columns. The manners of arrangements of the plurality of columns are similar to the manners of arrangements of the plurality of rows, which are not repeated herein.

In the embodiments of the present disclosure, colors of light emitted by sub-pixels of the plurality of second-type electrode patterns 1032 are the same, and colors of light emitted by sub-pixels of the plurality of third-type electrode patterns 1033 are the same. Illustratively, the sub-pixels of the plurality of first-type electrode patterns 1031 are green sub-pixels, and colors of the light emitted by the green sub-pixels are green. The sub-pixels of the plurality of second-type electrode patterns 1032 are one of red sub-pixels and blue sub-pixels, and the sub-pixels of the plurality of third-type electrode patterns 1033 are the other of red sub-pixels and blue sub-pixels. Illustratively, the sub-pixels of the plurality of second-type electrode patterns 1032 are the red sub-pixels, and the sub-pixels of the plurality of third-type electrode patterns 1033 are the blue sub-pixels. Colors of the light emitted by the red sub-pixels are red, and colors of the light emitted by the blue sub-pixels are blue. That is, in the embodiments of the present disclosure, one pixel circuit is configured to drive two green sub-pixels, and one pixel circuit is configured to drive one red sub-pixel or one blue sub-pixel.

In the embodiments of the present disclosure, referring to FIG. 1, two first pixel circuits A1 and three second pixel circuits A2 that are adjacent form a circuit set A, at least two second electrode patterns 1031b form an electrode pattern set, and one electrode pattern set, one fourth electrode pattern 1032b, and one sixth electrode pattern 1033b that are adjacent form a pattern set B. Each of the pattern sets B corresponds to one of the circuit sets A, and for each of the pattern sets B and the corresponding circuit set A, an orthogonal projection of the pattern set B on the base substrate 101 is overlapped with an orthogonal projection of the corresponding circuit set A on the base substrate 101.

In some embodiments, for each circuit set A and the pattern set B corresponding to the circuit set A, a space of the circuit set A (five pixel circuits) is equivalent to a space of the pattern set B (four electrode patterns), that is, five pixel circuits are correspondingly disposed on a lower side of the four electrode patterns.

For each circuit set A and the pattern set B corresponding to the circuit set A, the circuit set A includes three second pixel circuits A2. A first second pixel circuit A2 is connected to one second electrode pattern 1031b in the electrode pattern set in the pattern set B, a second second pixel circuit A2 is connected to the fourth electrode pattern 1032b in the pattern set B, and a third second pixel circuit A2 is connected to the sixth electrode pattern 1033b in the pattern set B. That is, in the five pixel circuits in each circuit set A, three second pixel circuits A2 are pixel circuits for driving four electrode patterns in the pattern set B in the second display region 101b.

In addition, two first pixel circuits A1 in one part of circuit sets A in the display panel 10 are connected to electrode patterns in the first display region 101a, and two first pixel circuits A1 in the other part of the circuit sets A in the display panel 10 are connected to a fixed voltage terminal. That is, in the circuit sets A in the display panel 10, two first pixel circuits A1 in some of the circuit sets A are pixel circuits for driving electrode patterns in the first display region 101a, and two first pixel circuits A1 in remaining circuit sets A are not connected to the electrode patterns in the first display region 101a and are used as the dummy pixel circuits to be connected to the fixed voltage terminal. As the dummy pixel circuits are connected to the fixed voltage terminal, an effect of the dummy pixel circuits on signals transmitted by signal lines in the display panel is avoided, and thus the display effect of the display panel 10 is ensured.

In the embodiments of the present disclosure, the circuit sets A of the first pixel circuits A1 connected to the electrode patterns in the first display region 101a are closer to the first display region 101a than the circuit sets A of the first pixel circuits A1 connected to the fixed voltage terminal are. As such, a length of the second connection trace L2 for connecting the electrode patterns in the first display region 101a and the first pixel circuits A1 in the second display region 101b is less, such that the display effect of the display panel 10 is ensured.

In the embodiments of the present disclosure, one first pixel circuit A1 supplies the data drive signal to two first electrode patterns 1031a. In the case that the length of the second connection trace L2 for connecting the first pixel circuit A1 and the two first electrode patterns 1031a is great, the second connection trace L2 is prone to suffering from the resistance-capacitance interference, and thus the sub-pixels of the first electrode patterns 1031a does not emit light in a low grayscale.

Thus, referring to FIG. 1 and FIG. 2, a length of any second connection trace L2 along the pixel row direction X is less than a length of each fourth connection trace L4 along the pixel row direction X and a length of each fifth connection trace L5 along the pixel row direction X. That is, compared with the third electrode pattern 1032a and the fifth electrode pattern 1033a, the first electrode pattern 1031a is preferentially connected to the first pixel circuit A1 in the second display region 101b via the second connection trace L2. Thus, the length of the second connection trace L2 connected to the first electrode pattern 1031a is reduced, the strength of the resistance-capacitance interference on the second connection trace L2 is weakened, and the sub-pixels in the first display region 101a display normally in the low grayscale.

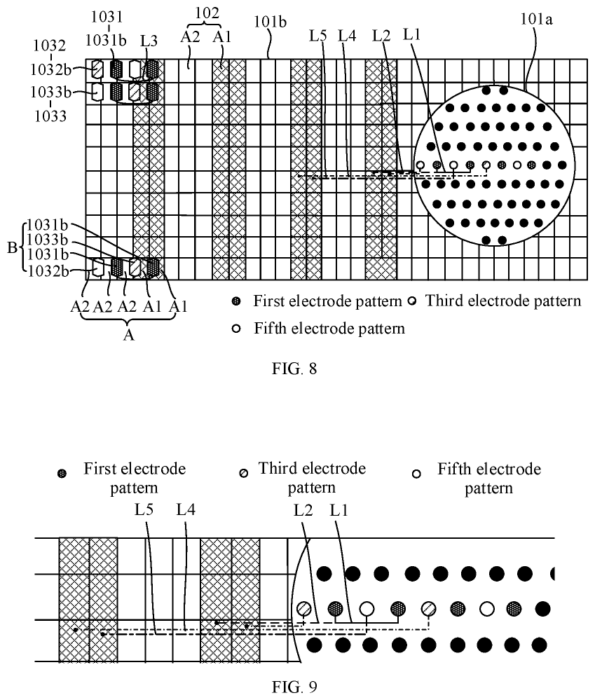

Referring to FIG. 8 and FIG. 9, for each connection trace in the plurality of second connection traces L2, the plurality of fourth connection traces L4, and the plurality of fifth connection traces L5, a length of the connection trace along the pixel row direction X is positively correlated with a distance between the electrode pattern in the first display region 101a connected to the connection trace and the second display region 101b along the pixel row direction X. That is, the electrode patterns in the first display region 101a are sequentially connected to the first pixel circuits A1 in the second display region 101b via the second connection traces L2.

Referring to FIG. 3, the second display region 101b includes a first display sub-region 101b1, a second display sub-region 101b2, and a third display sub-region 101b3. The first display sub-region 101b1 and the first display region 101a are arranged in a pixel column direction Y, the second display sub-region 101b2 and the first display region 101a are arranged along the pixel row direction X, the third display sub-region 101b3 and the first display sub-region 101b1 are arranged along the pixel row direction X, and the third display sub-region 101b3 and the second display sub-region 101b2 are arranged in the pixel column direction Y.

The second display region 101b includes one first display sub-region 101b1, two second display sub-regions 101b2, and two third display sub-regions 101b3. The first display sub-region 101b1 is disposed on a lower side of the first display region 101a, the two second display sub-regions 101b2 are respectively disposed on two sides of the first display region 101a along the pixel row direction X, and the two third display sub-regions 101b3 are respectively disposed on two sides of the first display sub-region 101b1 along the pixel row direction X. In some embodiments, the second display sub-region 101b2 and the third display sub-region 101b3 both are transition display regions of the display panel.

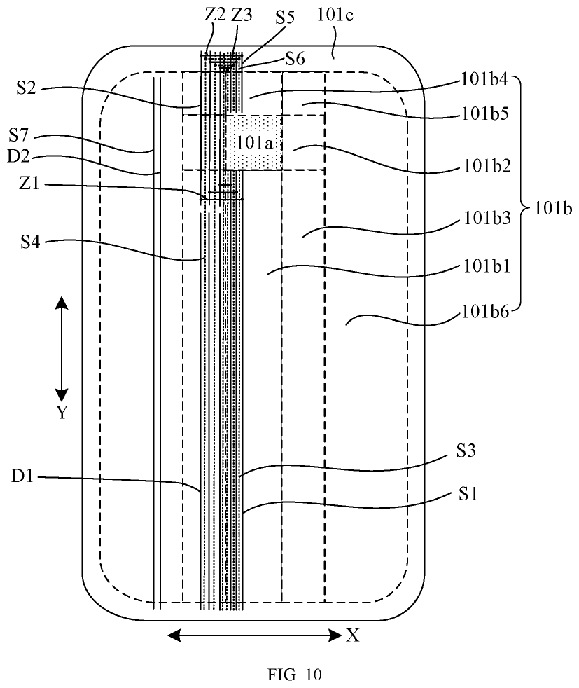

Referring to FIG. 10, the display panel 10 further includes a plurality of first data lines S1 in the first display sub-region 101b1, a plurality of second data lines S2 in the second display sub-region 101b2 and the third display sub-region 101b3, a plurality of first patch codes Z1 in the first display sub-region 101b1 and the third display sub-region 101b3.

The plurality of first data lines S1 are arranged along the pixel row direction X and extend in the pixel column direction Y, the plurality of second data lines S2 are arranged along the pixel row direction X and extend in the pixel column direction Y, and the plurality of first patch codes Z1 are arranged in the pixel column direction Y and extend along the pixel row direction X. A first end of each first data line S1 is configured to be connected to a data drive circuit, a second end of each first data line S1 is connected to a first end of one first patch code Z1, a second end of each first patch codes Z1 is connected to a first end of one second data line S2. Thus, the data drive signal supplied by the data drive circuit is transmitted by the first data line S1, the first patch code Z1, and the second data line S2, and the data drive signals transmitted by one first data line S1, one first patch code Z1, and one second data line S2 that are connected are the same.

Compared with a boundary of the third display sub-region 101b3 distal from the second display sub-region 101b2, the first end of the second data line S2 is closer to a boundary of the third display sub-region 101b3 proximal to the second display sub-region 101b2. That is, a length of the second data line S2 in the pixel column direction Y is slightly greater than a length of the second display sub-region 101b2 in the pixel column direction Y, and the first end of the second data line S2 in the third display sub-region 101b3 is convenient to be connected to the second end of the first patch code Z1 in the third display sub-region 101b3 only by disposing the first end of the second data line S2 in the third display sub-region 101b3.

Each first data line S1 is further connected to one column of the second pixel circuits A2 configured to be connected to first target electrode patterns in the first display sub-region 101b1, and each second data line S2 is further connected to one column of the first pixel circuits A1 configured to be connected to second target electrode patterns in the second display sub-region 101b2.

For the first data line S1 and the second data line S2 connected via one first patch code Z1, one column of the first target electrode patterns connected to the first data line S1 via one column of the second pixel circuits A2 and one column of the second target electrode patterns connected to the second data line S2 via one column of the first pixel circuits A1 are arranged in the pixel column direction Y, such that the same column of the electrode patterns in the first display region 101a and the first display sub-region 101b1 receive the same data drive signal.

In the embodiments of the present disclosure, the first target electrode patterns are at least one of the fourth electrode patterns 1032b and the sixth electrode patterns 1033b, and the second target electrode patterns are at least one of the third electrode patterns 1032a and the fifth electrode patterns 1033a.

In a first optional implementation, the first target electrode patterns are the fourth electrode patterns 1032b or the sixth electrode patterns 1033b, and the second target electrode patterns are the third electrode patterns 1032a or the fifth electrode patterns 1033a. Referring to FIG. 10, the display panel 10 further includes a plurality of third data lines S3 in the first display sub-region 101b1 and a plurality of fourth data lines S4 in the second display sub-region 101b2 and the third display sub-region 101b3. The plurality of third data lines S3 are arranged along the pixel row direction X and extend in the pixel column direction Y, and the plurality of fourth data lines S4 are arranged along the pixel row direction X and extend in the pixel column direction Y. A first end of each third data line S3 and a first end of each fourth data line S4 both are configured to be connected to the data drive circuit, and each third data line S3 is further connected to one column of the second pixel circuits A2 configured to be connected to the second electrode patterns 1031b in the first display sub-region 101b1, and each fourth data line S4 is further connected to one column of the first pixel circuits A1 configured to be connected to the first electrode patterns 1031a in the second display sub-region 101b2.

That is, the data drive signal supplied by the data drive circuit is transmitted to one column of the second pixel circuits A2 in the first display sub-region 101b1 via the third data lines S3, such that one column of the second electrode patterns 1031b connected to the one column of the second pixel circuits A2 are driven. In addition, the data drive signal supplied by the data drive circuit is transmitted to one column of the first pixel circuits A1 in the second display sub-region 101b2 via the fourth data lines S4, such that one column of the first electrode patterns 1031a connected to the one column of the first pixel circuits A1 are driven.

In the first optional implementation, the data drive signals received by the same column of the second-type electrode patterns 1032 (the third electrode patterns 1032a and the fourth electrode patterns 1032b) in the display panel are transmitted by the first patch codes Z1, the data drive signals received by the same column of the third-type electrode patterns 1033 (the fifth electrode patterns 1033a and the sixth electrode patterns 1033b) in the display panel are transmitted by the first patch codes Z1, and the data drive signals received by the same column of the first-type electrode patterns 1031 (the first electrode patterns 1031a and the second electrode patterns 1031b) in the display panel are transmitted by the data lines (the third data lines S3 and the fourth data lines S4) connected to the data drive circuit not the first patch codes Z1. Thus, the length of the data lines connected to the first-type electrode patterns 1031 (in the manner of transmission with the patch codes, a length of the data line is a sum of a length of the connected data line and the patch code) is reduced, and the resistance and the capacitance of the data line are reduced, the drive capacity of the pixel circuit is improved, and the display effect is improved.

Referring to FIG. 3, the second display region 101b further includes a fourth display sub-region 101b4 and a fifth display sub-region 101b5. The fourth display sub-region 101b4 is disposed on a side, distal from the first display sub-region 101b1, of the first display region 101a, the fifth display sub-region 101b5 and the fourth display sub-region 101b4 are arranged along the pixel row direction X. Illustratively, the second display region 101b further includes one fourth display sub-region 101b4 and two fifth display sub-regions 101b5. The one fourth display sub-region 101b4 is disposed on an upper side of the first display region 101a, and the two fifth display sub-regions 101b5 are respectively disposed on two sides of the fourth display sub-region 101b4 along the pixel row direction X. The fifth display sub-region 101b5 is a transition display region.

In some embodiments, the first display region 101a is disposed inside the second display region 101b, and the second display region 101b completely surrounds the first display region 101a. Thus, for transmission of the data drive signal to the fourth display sub-region 101b4 in the first display region 101a distal from the first display sub-regions 101b1, the display panel 10 includes a plurality of second patch codes Z2, a plurality of third patch codes Z3, and a plurality of fifth data lines S5 and a plurality of sixth data lines S6 that are disposed in the fourth display sub-region 101b4. The plurality of fifth data lines S5 are arranged along the pixel row direction X and extend in the pixel column direction Y, the plurality of sixth data lines S6 are arranged along the pixel row direction X and extend in the pixel column direction Y, the plurality of second patch codes Z2 are arranged in the pixel column direction Y and extend along the pixel row direction X, and the plurality of third patch codes Z3 are arranged in the pixel column direction Y and extend along the pixel row direction X.

A second end of each second data lines S2 is connected to a first end of one second patch codes Z2, a second end of each second patch codes Z2 is connected to a first end of each fifth data lines S5, and each fifth data lines S5 is further connected to one column of the second pixel circuits A2 configured to be connected to the first target electrode patterns in the fourth display sub-region 101b4. A second end of each fourth data lines S4 is connected to a first end of one third patch codes Z3, a second end of each third patch codes Z3 is connected to a first end of each sixth data lines S6, and each sixth data lines S6 is further connected to one column of the second pixel circuits A2 configured to be connected to the second electrode patterns 1031b in the fourth display sub-region 101b4. As such, the data drive circuit supplies the data drive signal to one column of the second pixel circuits A2 configured to be connected to the first target electrode patterns in the fourth display sub-region 101b4 via the first data line S1, the first patch code Z1, the second data line S2, the second patch code Z2, and the fifth data line S5, and supplies the data drive signal to one column of the second pixel circuits A2 configured to be connected to the second electrode patterns 1031b in the fourth display sub-region 101b4 via the fourth data line S4, the third patch code Z3, and the sixth data line S6. That is, in this manner, the second electrode patterns 1031b in the fourth display sub-region 101b4 receive the data drive signal in a patch code signal manner.

Referring to FIG. 3, the base substrate 101 further includes a periphery region 101c surrounding the second display region 101b. Second ends of the plurality of second data lines S2, the plurality of second patch codes Z2, first ends of the plurality of fifth data lines S5, second ends of the plurality of fourth data lines S4, the plurality of third patch codes Z3, and first ends of spare sixth data lines S6 are all disposed in the periphery region 101c and are disposed in a region of the fourth display sub-region 101b4 distal from the first display region 101a. That is, a connection position of the second data line S2 and the second patch code Z2, a connection position of the second patch code Z2 and the fifth data line S5, a connection position of the fourth data line S4 and the third patch code Z3, and a connection position of the third patch code Z3 and the sixth data line S6 are all disposed in the periphery region 101c.

In a second optional implementation, the first target electrode patterns are one of the second electrode patterns 1031b, the fourth electrode patterns 1032b, and the sixth electrode patterns 1033b, and the second target electrode patterns are one of the first electrode patterns 1031a, the third electrode patterns 1032a, and the fifth electrode patterns 1033a.

In the first optional implementation, the data drive signals received by the same column of the second-type electrode patterns 1032 (the third electrode patterns 1032a and the fourth electrode patterns 1032b) in the display panel are transmitted by the first patch codes Z1, the data drive signals received by the same column of the third-type electrode patterns 1033 (the fifth electrode patterns 1033a and the sixth electrode patterns 1033b) in the display panel are transmitted by the first patch codes Z1, and the data drive signals received by the same column of the first-type electrode patterns 1031 (the first electrode patterns 1031a and the second electrode patterns 1031b) in the display panel are transmitted by the first patch codes Z1.

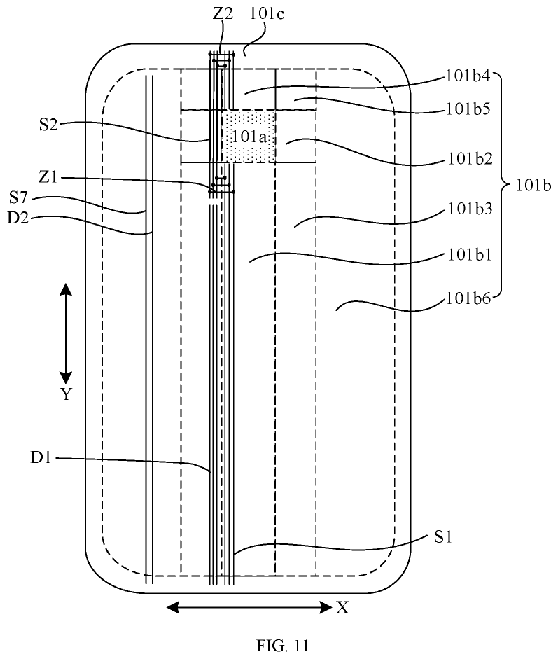

In the case that the second display region 101b completely surrounds the first display region 101a, referring to FIG. 11, the second display region 101b further includes the fourth display sub-region 101b4 and the fifth display sub-region 101b5. Thus, for transmission of the data drive signal to the fourth display sub-region 101b4 in the first display region 101a distal from the first display sub-regions 101b1, the display panel 10 includes a plurality of second patch codes Z2 and a plurality of fifth data lines S5 in the fourth display sub-region 101b4.

The plurality of fifth data lines S5 are arranged along the pixel row direction X and extend in the pixel column direction Y, and the plurality of second patch codes Z2 are arranged in the pixel column direction Y and extend along the pixel row direction X. A second end of each second data lines S2 is connected to a first end of one second patch codes Z2, a second end of each second patch codes Z2 is connected to a first end of each fifth data lines S5, and each fifth data lines S5 is further connected to one column of the second pixel circuits A2 configured to be connected to the first target electrode patterns in the fourth display sub-region 101b4. As such, the data drive circuit supplies the data drive signal to one column of the second pixel circuits A2 configured to be connected to the first target electrode patterns in the fourth display sub-region 101b4 via the first data line S1, the first patch code Z1, the second data line S2, the second patch code Z2, and the fifth data line S5.

Referring to FIG. 11, the base substrate 101 further includes the periphery region 101c surrounding the second display region 101b. Second ends of the plurality of second data lines S2, the plurality of second patch codes Z2, the plurality of fifth data lines S5, and first ends of the plurality of fifth data lines S5 are all disposed in the periphery region 101c and are disposed in a region of the fourth display sub-region 101b4 distal from the first display region 101a. That is, a connection position of the second data line S2 and the second patch code Z2 and a connection position of the second patch code Z2 and the fifth data line S5 are all disposed in the periphery region 101c.

In the embodiments of the present disclosure, the display panel 10 further includes a plurality of first dummy data lines D1 in the third display sub-region 101b3. The plurality of first dummy data lines D1 are arranged along the pixel row direction X and extend in the pixel column direction Y, one end of the first dummy data line D1 is configured to be connected to a fixed voltage terminal, and the first dummy data lines D1 are further connected to one column of the first pixel circuits A1 in the third display sub-region 101b3.

The first pixel circuits A1 in the third display sub-region 101b3 are dummy pixel circuits, and the dummy pixel circuits indicate pixel circuits not connected to any electrode pattern. The fixed voltage terminal supplies a fixed signal to the dummy pixel circuit via the first dummy data line D1, such that an effect of the dummy pixel circuit on the signals transmitted by the signal lines in the display panel is avoided, and the display effect of the display panel 10 is ensured.

In some embodiments, the first dummy data lines D1 and other data lines (for example, the second data line S2) in the above embodiments are disposed in the same layer or different layers, which is not limited in the embodiments of the present disclosure. In the case that the first dummy data lines D1 and other data lines in the above embodiments are disposed in the same layer, a space is present between the first dummy data lines D1 and other data lines, such that the first dummy data lines D1 transmit the fixed voltage signal, and the other data lines transmit data drive signal.

For the above first implementation, in the plurality of first dummy data lines D1 in the third display sub-region 101b3 in the display panel 10, one part of the first dummy data lines D1 and other data lines are disposed in the same layer, and the other part of the first dummy data lines D1 and other data lines are disposed in different layers. In some embodiments, each first dummy data line D1 in the same layer as other data lines and one second data line S2 are collinear, and a space is present between each first dummy data line D1 in the same layer as other data lines and one second data line S2. As the fourth data line S4 is disposed in the third display sub-region 101b3, and is connected to the data drive circuit by running through the third display sub-region 101b3, the first dummy data line D1 in different layers from the fourth data line S4 is connected to one column of first pixel circuits A1 in the third display sub-region 101b3 for avoidance of the fourth data line S4. The one column of first pixel circuits A1 in the third display sub-region 101b3 and the first pixel circuits A1 connected to the fourth data line S4 in the second display sub-region 101b2 are in the same column.

For the above second implementation, in the plurality of first dummy data lines D1 in the third display sub-region 101b3 in the display panel 10, all first dummy data lines D1 and other data lines are disposed in the same layer or in different layers.

In the embodiments of the present disclosure, the second display region 101b further includes a sixth display sub-region 101b6. The sixth display sub-region 101b6 is also referred to as a normal display region. In some embodiments, the second display region 101b includes two sixth display sub-regions 101b6. The two sixth display sub-regions 101b6 are respectively disposed on two sides of a first third display sub-region 101b3, the first display sub-region 101b1, and a second third display sub-region 101b3 along the pixel row direction X, and are disposed on two sides of a first second display sub-region 101b2, the first display region 101a, and a second second display sub-region 101b2 along the pixel row direction X.

The display panel 10 further includes a plurality of seventh data lines S7 in the sixth display sub-region 101b6 and a plurality of second dummy data lines D2 in the sixth display sub-region 101b6. One end of each seventh data line S7 is configured to be connected to a data drive circuit, and each seventh data line S7 is further connected to one column of the second pixel circuits A2 in the sixth display sub-region 101b6, such that the data drive circuit supplies the data drive signal to the second pixel circuits A2 via the seventh data line S7. One end of each second dummy data line D2 is configured to be connected to a fixed voltage terminal, and each second dummy data line D2 is further connected to one column of the first pixel circuits A1 in the sixth display sub-region, such that the fixed voltage terminal supplies the voltage signal to the first pixel circuits A1 via the second dummy data line D2. The first pixel circuits A1 in the sixth display sub-region 101b6 are dummy pixel circuits.

In the embodiments of the present disclosure, the third connection traces L3 are disposed in different layers from the first connection traces L1 and the second connection traces L2. For example, referring to FIG. 4, the display panel 10 includes a connection layer 104 between the drive circuit layer 102 and the first electrode layer 103. The first connection traces L1 and the second connection traces L2 are disposed in the connection layer 104. That is, the first connection traces L1 and the second connection traces L2 are disposed between the drive circuit layer 102 and the first electrode layer 103. The third connection traces L3 are disposed in the first electrode layer 103.

In some embodiments, an electrode pattern in the first electrode layer 103 is a laminated structure of a first film layer, a second film layer, and a third film layer. The first film layer and the third film layer are made of the indium tin oxide (ITO), and the second film layer is made of the argentum (Ag). That is, the electrode pattern is ITO/Ag/ITO. The third connection traces L3 being disposed in the first electrode layer 103 indicates that the third connection traces L3 are the same as the electrode pattern, that is, the laminated structure of ITO/Ag/ITO. In some embodiments, the third connection traces L3 are one ITO layer (for example, the first film layer or the third film layer) in the electrode pattern.

In some embodiments, the connection layer 104 includes at least one conductive layer and at least one insulative layer, and a side of each conduction layer distal from the base substrate 101 is provided with one insulative layer.

Illustratively, the connection layer 104 includes a first conduction layer 1041, a first insulative layer 1042, a second conduction layer 1043, a second insulative layer 1044, a third conduction layer 1045, and a third insulative layer 1046 that are sequentially laminated on a side, distal from the base substrate 101, of the drive circuit layer 102. Each conduction layer in the first conduction layer 1041, the second conduction layer 1043, and the third conduction layer 1045 includes a plurality of first connection traces L1 and/or a plurality of second connection traces L2. The first insulative layer 1042 is provided with a first via, the second insulative layer 1044 is provided with a second via, and the third insulative layer 1046 is provided with a third via. The first conduction layer 1041 is electrically connected to the second conduction layer 1043 through the first via, the second conduction layer 1043 is electrically connected to the third conduction layer 1045 through the second via, and the third conduction layer 1045 is electrically connected to the first electrode layer 103 through the third via.

In the embodiments of the present disclosure, the connection traces (the second connection traces L2, the fourth connection traces L4, and the fifth connection traces L5) for connecting the first pixel circuit A1 in the second display region 101b and the electrode pattern in the first display region 101a are uniformly disposed in three conduction layers. By arranging positions of the connection traces reasonably, the problem of short circuit or crosstalk due to the less distance between adjacent connection traces is avoided.

It should be noted that in the case that an area of the first display region 101a is less, a precision of manufacturing the connection traces (the second connection traces L2, the fourth connection traces L4, and the fifth connection traces L5) between the first pixel circuit A1 in the second display region 101b and the electrode pattern in the first display region 101a is great, and a width of the connection trace can be reduced, all connection traces are disposed in two conduction layers even one conduction layer, such that a number of mask plates used in manufacturing process is reduced, and the process is simplified. In addition, the transmissivity of the first display region 101a is improved, the overall thickness of the display panel 10 is reduced, and the display panel is thin and light.

Referring to FIG. 4, the conduction layer is further provided with a connection portion configured to connect the connection trace and the pixel circuit, or connect the connection traces in different layers, or connect the connection trace and the electrode pattern in the first electrode layer 103. For example, the first conduction layer 1041 includes a plurality of first connection portions 1041a, the second conduction layer 1043 includes a plurality of second connection portions 1043a, and the third conduction layer 1045 includes a plurality of third connection portions 1045a.

FIG. 4 is shown by taking the first connection trace L1 being in the third conduction layer 1045 and the second connection trace L2 being in the first conduction layer 1041 as an example. In the second display region 101b, the second pixel circuit A2 is connected to the first connection portion 1041a, the first connection portion 1041a is connected to the second connection portion 1043a, the second connection portion 1043a is connected to the third connection portion 1045a, and the third connection portion 1045a is connected to one electrode pattern (the second electrode pattern 1031b, the fourth electrode pattern 1032b, or the sixth electrode pattern 1033b). Where the third connection portion 1045a is connected to one second electrode pattern 1031b, the third connection portion 1045a is further connected to the third connection trace L3, the third connection trace L3 is connected to another third connection portion 1045a, and the another third connection portion 1045a is connected to another second electrode pattern 1031b. In the first display region 101a, the second connection trace L2 is connected to the first pixel circuit A1 through one first connection portion 1041a and is connected to the second connection portion 1043a through another first connection portion 1041a, the second connection portion 1043a is connected to the third connection portion 1045a, and the third connection portion 1045a is connected to one electrode pattern (the first electrode pattern 1031a, the third electrode pattern 1032a, or the fifth electrode pattern 1033a). Where the third connection portion 1045a is connected to one first electrode pattern 1031a, the third connection portion 1045a is further connected to the first connection trace L1, the first connection trace L1 is connected to another third connection portion 1045a, and the another third connection portion 1045a is connected to another second electrode pattern 1031b.

An orthogonal projection of the third connection portion 1045a on the base substrate 101 is at least partially overlapped with an orthogonal projection of the electrode pattern connected to the third connection portion 1045a on the base substrate 101, such that the electrode pattern is connected to the third connection portion 1045a by running through the third via in the third insulative layer 1046. Orthogonal projections of the second connection portion 1043a and the third connection portion 1045a that are connected on the base substrate 101 are at least partially overlapped, such that the third connection portion 1045a is connected to the second connection portion 1043a by running through the second via in the second insulative layer 1044. Orthogonal projections of the first connection portion 1041a and the second connection portion 1043a that are connected on the base substrate 101 are at least partially overlapped, such that the second connection portion 1043a is connected to the first connection portion 1041a by running through the first via in the first insulative layer 1042. Orthogonal projections of the first connection portion 1041a and the pixel circuit that are connected on the base substrate 101 are at least partially overlapped, such that the second connection portion 1043a is connected to the pixel circuit. As such, by disposing the connection portion in the conduction layers, connections between the pixel circuits and the electrode patterns are more stable.

In some embodiments, the first conduction layer 1041, the second conduction layer 1043, and the third conduction layer 1045 all include transparent conductive materials. For example, the first conduction layer 1041, the second conduction layer 1043, and the third conduction layer 1045 are all made of the indium tin oxide or the indium zinc oxide. Insulative layers in the connection layer 104 all include transparent conductive materials. For example, the first insulative layer 1042, the second insulative layer 1044, and the third insulative layer 1046 are all made of polyimide (PI).

In the embodiments of the present disclosure, referring to FIG. 4, the display panel further includes a light-emitting film layer 105, a pixel definition layer 106, a second electrode layer 107, a package layer 108, and a buffer layer 109. The package layer 108 is disposed on a side, distal from the base substrate 101, of the second electrode layer 107 to package the display panel 10. The buffer layer is disposed between the base substrate 101 and the drive circuit layer 102.

The first electrode layer 103, the pixel definition layer 106, the light-emitting film layer 105, and the second electrode layer 107 form a plurality of light-emitting devices, for example, a plurality of OLEDs. The light-emitting film layer 105 includes a plurality of light-emitting layers 1051, and a plurality of openings are defined in the pixel definition layer 106. Each opening exposes one electrode pattern in the first electrode layer 103, each light-emitting layer 1051 is disposed in one opening and is in contact with the electrode pattern, and a portion of the second electrode layer 107 in the opening is determined as a second electrode of the light-emitting device. As such, the electrode pattern (the anode), the light-emitting layer 1051, and the second electrode (the cathode) that are sequentially laminated form the light-emitting device.

The pixel circuit in the drive circuit layer 102 is electrically connected to the light-emitting device. Illustratively, the pixel circuit is electrically connected to the electrode pattern in the first electrode layer 103 in the light-emitting device to control the light-emitting device to emit light.

In some embodiments, the drive circuit layer 102 includes a semiconductor layer 10201, a first gate insulative layer (GI) 10202, a first gate layer 10203, a second gate insulative layer 10204, a second gate layer 10205, an interlayer dielectric (ILD) layer 10206, a first source and drain layer 10207, a passivation layer (PVX) 10208, an intermediate source and drain layer 10209, a first planarization layer (PLN) 10210, a second source and drain layer 10211, and a second planarization layer 10212. A plurality of pixel circuits in the drive circuit layer 102 are arranged in arrays, and each pixel circuit includes a plurality of thin-film transistors. The above first conduction layer 1041 in the connection layer 104 is disposed on a side, distal from the base substrate 101, of the second planarization layer 10212. The first insulative layer 1042 is also referred to as a third planarization layer, the second insulative later 1044 is also referred to as a fourth planarization layer, and the third insulative later 1046 is also referred to as a fifth planarization layer. The pixel circuit in the drive circuit layer 102 is electrically connected to the light-emitting device through the connection layer 104.

In some embodiments, the first source and drain layer 10207 includes sources and drains in the thin-film transistors in the pixel circuits, and spaces are present between the sources and the drains. In some embodiments, the first source and drain layer 10207 further includes the patch codes (the first patch codes Z1, the second patch codes Z2, and the third patch codes Z3) in the above embodiments. The intermediate source and drain layer 10209 includes power traces (for example, VDD traces) for providing power signals to the display panel 10. Alternatively, the intermediate source and drain layer 10209 includes the patch codes (the first patch codes Z1, the second patch codes Z2, and the third patch codes Z3) in the above embodiments. The second source and drain layer includes the data lines (the first data lines S1, the second data lines S2, the third data lines S3, the fourth data lines S4, the fifth data lines S5, the sixth data lines S6, and the seventh data lines S7) and the dummy data lines (the first dummy data lines D1 and the second dummy data lines D2) in the above embodiments.

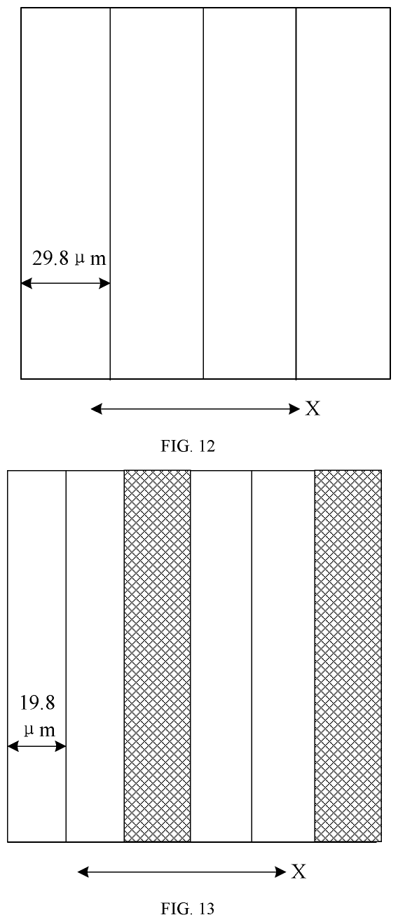

It should be noted that for the design of pixel circuits in a display panel with a great pixel per inch (PPI), in the case that a sixth display sub-region (the normal display region) in the second display region is only disposed with pixel circuits for driving electrode patterns in the second display region and is not provided with the dummy pixel circuit, and each pixel circuit drives one electrode pattern, referring to FIG. 12, a space of each pixel circuit along the pixel row direction is great and is 29.8 μm. In this case, for improvement of the transmittance of the first display region, the pixel circuits for driving the electrode patterns in the first display region are disposed in the second display sub-region (the transition display region) in the second display region, such that arrangements of the pixel circuits in different sub-regions in the second display region are different, and the uniformity of the pixel circuits in the display panel is poor.

As such, for improvement of the uniformity of the pixel circuits in the display panel, the dummy pixel circuits are disposed in the sixth display sub-region. For example, in FIG. 13, one first pixel circuit (the dummy pixel circuit) is designed for each two second pixel circuits, that is, a design of another one pixel circuit for two pixel circuits (another one pixel circuit for two pixel circuits indicates that positions of two second pixel circuits are required originally, and one addition dummy pixel circuit is disposed). In FIG. 12, positions of four pixel circuits are required originally, and six pixel circuits are disposed. In this manner, a space of each pixel circuit along the pixel row direction is less and is 19.8 μm, and thus the manufacturing process is difficult.

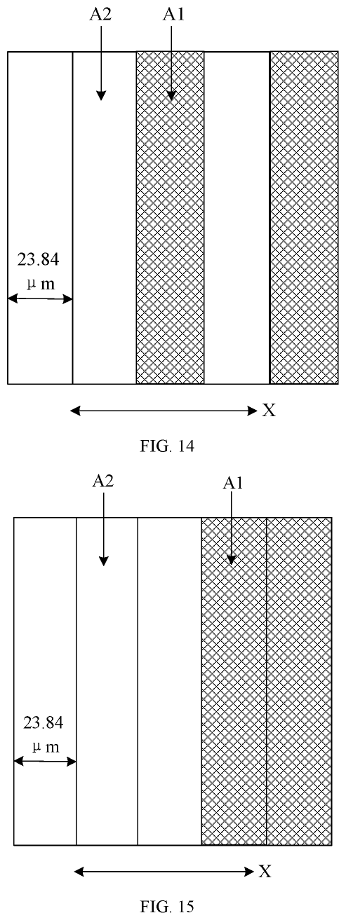

In the embodiments of the present disclosure, as two second electrode patterns are driven by one second pixel circuit, the number of the required pixel circuits is reduced. Compared with FIG. 13, in FIG. 14, positions of six pixel circuits are required originally, and only five pixel circuits are disposed. The space of each pixel circuit along the pixel row direction is great and is 23.83 μm, and thus the difficulty of manufacturing process is less. In addition, arrangements of the pixel circuits in different sub-regions in the second display region are different, and the uniformity of the pixel circuits in the display panel is poor.

Referring to FIG. 14, three second pixel circuits and two first pixel circuits in the five pixel circuits (one circuit set) are arranged in a manner of the second pixel circuit, the second pixel circuit, the first pixel circuit, the second pixel circuit, and the first pixel circuit. Referring to FIG. 15, three second pixel circuits and two first pixel circuits in the five pixel circuits are arranged in a manner of the second pixel circuit, the second pixel circuit, the second pixel circuit, the first pixel circuit, and the first pixel circuit. In some embodiments, the arrangement is achieved in other manners, which is not limited in the embodiments of the present disclosure.

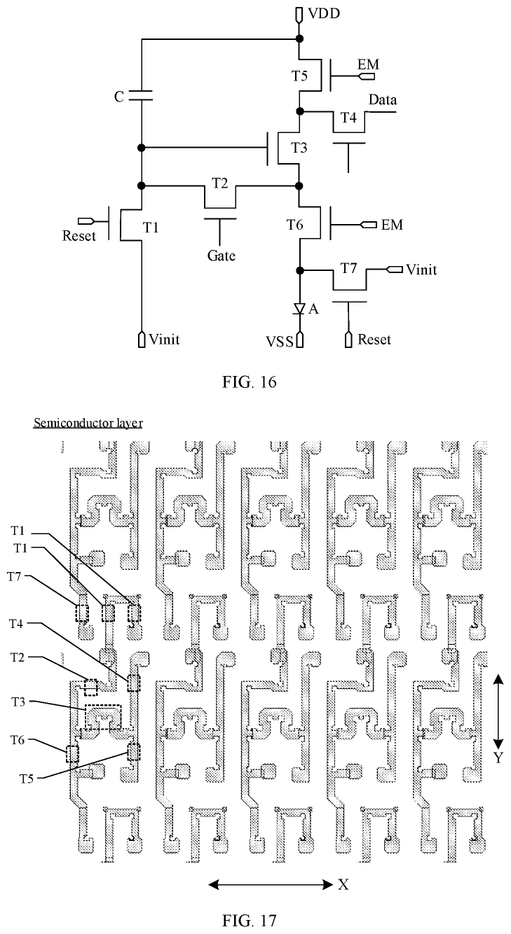

In the embodiments of the present disclosure, equivalent circuit diagrams of the first pixel circuit or the second pixel circuit are referred to as FIG. 16. The pixel circuit includes a plurality of thin-film transistors and one storage capacitor. The plurality of thin-film transistors includes a first reset control transistor T1, a threshold compensation transistor T2, a drive transistor T3, a data write transistor T4, a first light-emitting control transistor T5, a second light-emitting control transistor T6, and a third reset control transistor T7.

The storage capacitor Cst includes two capacitor plates Cst1 and Cst2. In the embodiments of the present disclosure, the capacitor plate Cst1 is also referred to as one terminal, a first terminal, a first electrode, or a first storage capacitor plate of the storage capacitor Cst, and the capacitor plate Cst2 is also referred to as the other terminal, a second terminal, a second electrode, or a second storage capacitor plate of the storage capacitor Cst.

A first electrode of the first reset control transistor T1 is electrically connected to a reset power signal line to receive a reset signal Vinit, a second electrode of the first reset control transistor T1 is electrically connected to a gate of the drive transistor T3, and a gate of the first reset control transistor T1 is electrically connected to a reset control signal line to receive a reset control signal Reset. A first electrode of the threshold compensation transistor T2 is connected to a first electrode of the drive transistor T3, a gate of the threshold compensation transistor T2 is electrically connected to a scan signal line to receive a scan signal Gate, and a second electrode of the threshold compensation transistor T2 is connected to the gate of the drive transistor T3. A first electrode of the data write transistor T4 is connected to a second electrode of the drive transistor T3, a gate of the data write transistor T4 is electrically connected to a scan signal line to receive a scan signal Gate, and a second electrode of data write transistor T4 is connected to a data line to receive a data drive signal Data. A first electrode of the first light-emitting control transistor T5 is electrically connected to a first power signal line, a second electrode of the first light-emitting control transistor T5 is electrically connected to the second electrode of the drive transistor T3, and a gate of the first light-emitting control transistor T5 is electrically connected to a light-emitting control signal line to receive a light-emitting control signal EM. A gate of the second light-emitting control transistor T6 is electrically connected to a light-emitting control signal line to receive a light-emitting control signal EM. A first electrode of the third reset control transistor T7 is connected to a reset power signal line to receive a reset signal Vinit, a second electrode of the third reset control transistor T7 is connected to an electrode pattern of the light-emitting device, and a gate of the third reset control transistor T7 is electrically connected to a reset control signal line to receive a reset control signal Reset. A first electrode of the storage capacitor Cst is electrically connected to a first power signal line, and a second electrode of the storage capacitor Cst is electrically connected to the gate of the drive transistor T3. In addition, a cathode of the light-emitting device is electrically connected to a second power signal line. The above first power signal line indicates a signal line outputting a voltage signal VDD, and the above second power signal line indicates a signal line outputting a voltage signal VSS.

FIG. 17 is a locally schematic diagram of a semiconductor layer in a display panel according to some embodiments of the present disclosure. Referring to FIG. 17, the semiconductor layer is in a curved or bent shape. The semiconductor layer includes semiconductor patterns (a channel region) and doping region patterns (a source and drain doping region) of transistors, and active layer patterns and doping region patterns of transistors in the same pixel circuit are integrated.

It should be noted that the semiconductor layer includes a low-temperature polycrystalline silicon layer, and the source region and the drain region are conducted by doping to achieve the electrical connection of the structures. That is, the semiconductor layer of transistors in each pixel circuit is an entire pattern formed by the p-type silicon. The transistors in the same pixel circuit include the (that is, the source region and the drain region) and the semiconductor pattern, and the semiconductor patterns of different transistors are spaced apart.

The semiconductor layer is made of the amorphous silicon, the polycrystalline silicon, the oxide semiconductor material, and the like. It should be noted that the above source region and the above drain region are regions doped with n-type or p-type impurities.

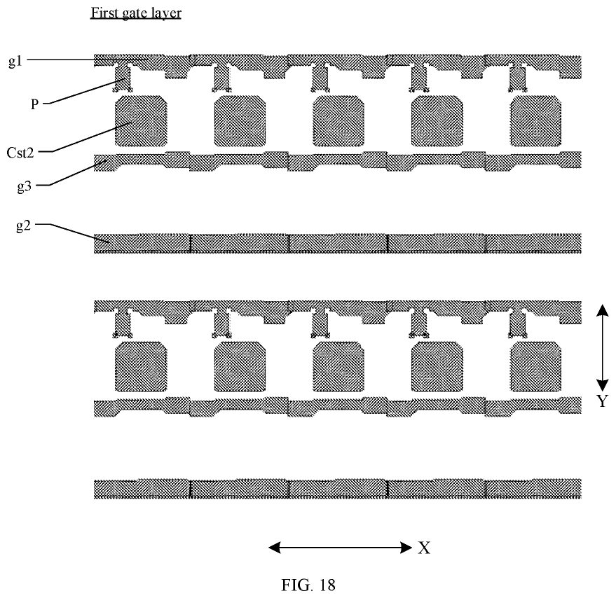

FIG. 18 is a locally schematic diagram of superposition of a first gate layer in a display panel according to some embodiments of the present disclosure. The display panel includes a first gate insulative layer on a side, distal from the base substrate, of the semiconductor layer, and the first gate insulative layer is configured to insulate the above semiconductor layer from the subsequently formed first gate layer. FIG. 18 shows the first gate layer in the display panel, and the first gate layer is disposed on the first gate insulative layer to insulate form the semiconductor layer. The first gate layer includes a second storage capacitor electrode Cst2, a plurality of scan signal lines g1, a plurality of reset control signal lines g2, and a plurality of light-emitting control signal lines g3 that extend along the pixel row direction X, and the first gate layer further includes gates of the transistors.

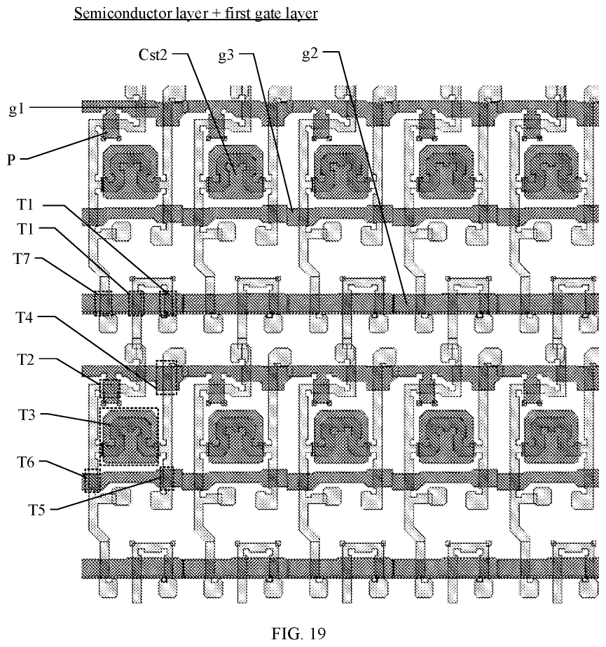

For example, in conjunction with FIF. 17 to FIG. 19, the gate of the data write transistor T4 is a portion of the scan signal line g1 overlapped with the semiconductor layer, the gate of the second light-emitting control transistor T6 is a first portion of the light-emitting control signal line g3 overlapped with the semiconductor layer, and the gate of the first light-emitting control transistor T5 is a second portion of the light-emitting control signal line g3 overlapped with the semiconductor layer. The gate of the first reset control transistor T1 is a first portion of the reset control signal line g2 overlapped with the semiconductor layer, and the gate of the third reset control transistor T7 is a second portion of the reset control signal line g2 overlapped with the semiconductor layer. The gate of the threshold compensation transistor T2 is a portion of a protrusion structure P protruded from the scan signal line g1 overlapped with the semiconductor layer. As shown in FIG. 18, the gate of the drive transistor T3 is a second storage capacitor electrode Cst2.

It should be noted that in FIG. 19, portions of the first gate layer overlapped with the semiconductor layer are shown by dashed rectangular boxes. For channel regions of the transistors, semiconductor layers on two sides of each channel region are determined as a first electrode and a second electrode of each transistor upon processes of ion doping. In some embodiments, the source and the drain of the transistor are symmetrical, and thus physics structures of the source and drain are the same. In the embodiments of the present disclosure, for distinguishing of the transistors, in addition to the gate determined as a control electrode, one electrode is directly described as the first electrode, and the other electrode is directly described as the second electrode, and thus the first electrode and the second electrode of each of all or part of transistors in the embodiments of the present disclosure are exchangeable according to requirements.

As shown in FIG. 18 and FIG. 19, the scan signal lines g1, the reset control signal lines g2, and the light-emitting control signal lines g3 are arranged in the pixel column direction Y. In the pixel column direction Y, the second storage capacitor electrode Cst2 (that is, the gate of the drive transistor T3) is disposed between the and the light-emitting control signal lines g3, and the protrusion structure P and the light-emitting control signal lines g3 is disposed on a side, proximal to the light-emitting control signal line g3, of the scan signal line g1.

In addition, a second gate insulative layer is formed on the above first gate layer, and is configured to insulate the first gate layer from the subsequently formed second gate layer.

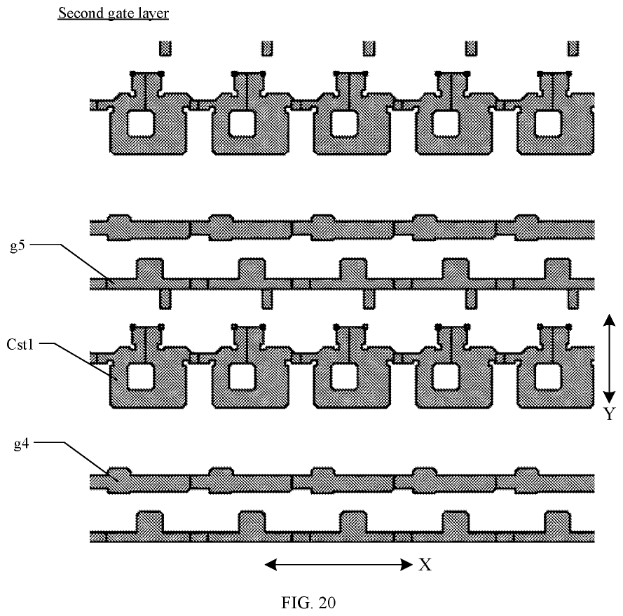

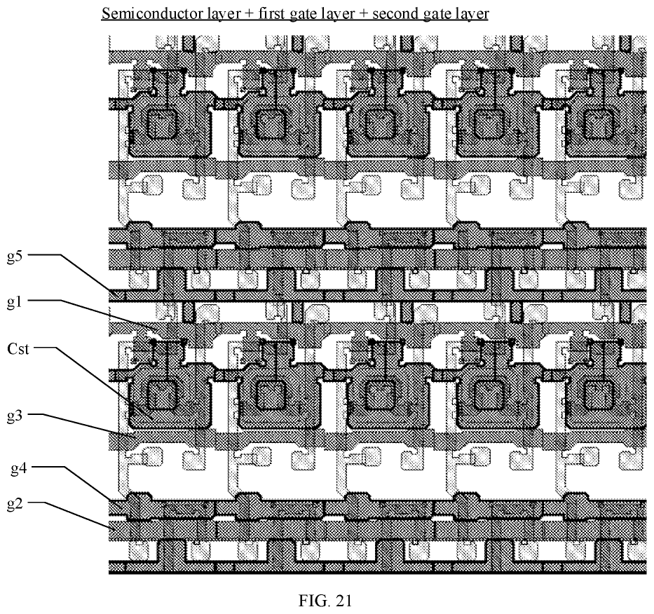

FIG. 20 is a locally schematic diagram of a second gate layer in a display panel according to some embodiments of the present disclosure. FIG. 21 is a locally schematic diagram of superposition of a semiconductor layer, a first gate layer, and a second gate layer in a display panel according to some embodiments of the present disclosure. As shown in FIG. 20 and FIG. 21, the second gate layer includes a first storage capacitor electrode Cst1, a plurality of first reset power signal lines g4 extending along the pixel row direction X, and a plurality of second reset power signal lines g5 extending along the pixel row direction X. The first storage capacitor electrode Cst1 and the second storage capacitor electrode Cst2 are at least partially overlapped to form a storage capacitor Cst.

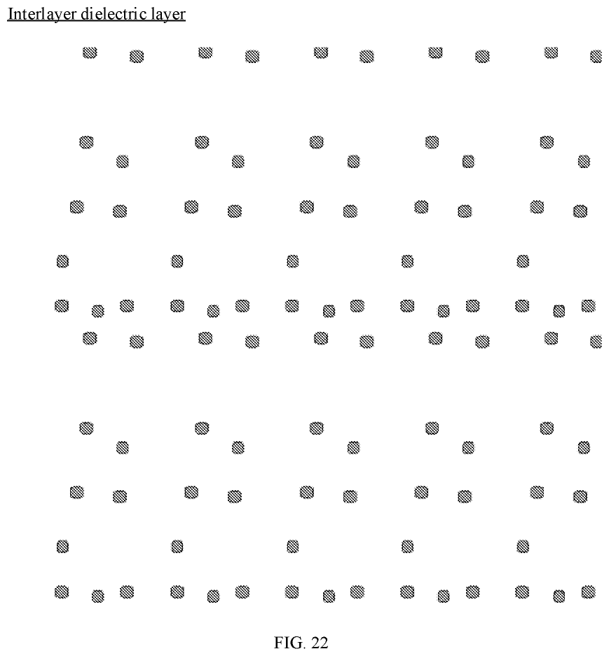

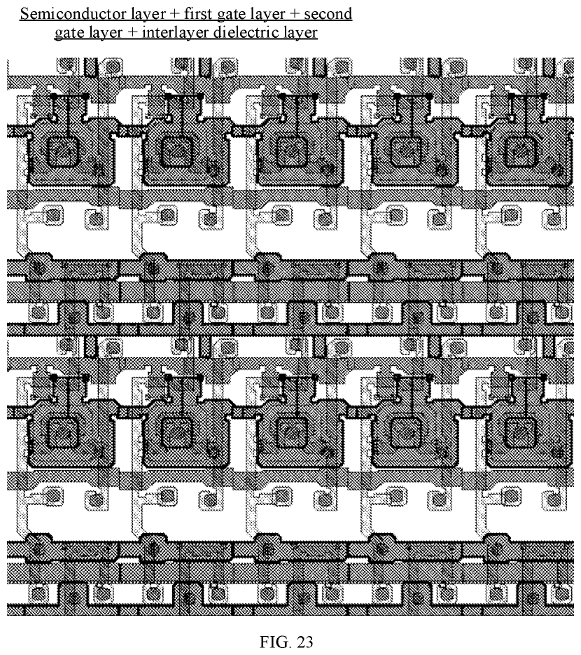

In addition, an interlayer dielectric layer is formed on the above second gate layer, and is configured to insulate the above second gate layer from the subsequently formed first source and drain layer. Referring to FIG. 22 and FIG. 23, for convenience of showing of vias in the interlayer dielectric layer (ILD), filling patterns are used to represent the vias in FIG. 22 to FIG. 23, and other regions without filling patterns are used to represent regions of the interlayer dielectric layer with real materials. It should be noted that the vias in the interlayer dielectric layer are used to connect subsequently formed film layers and film layers on a side, proximal to the base substrate, of the interlayer dielectric layer. That is, the vias are vias used to connect film layers.

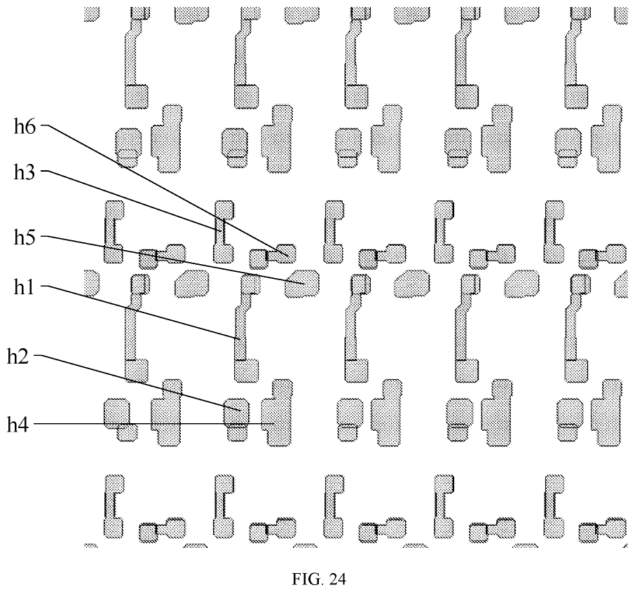

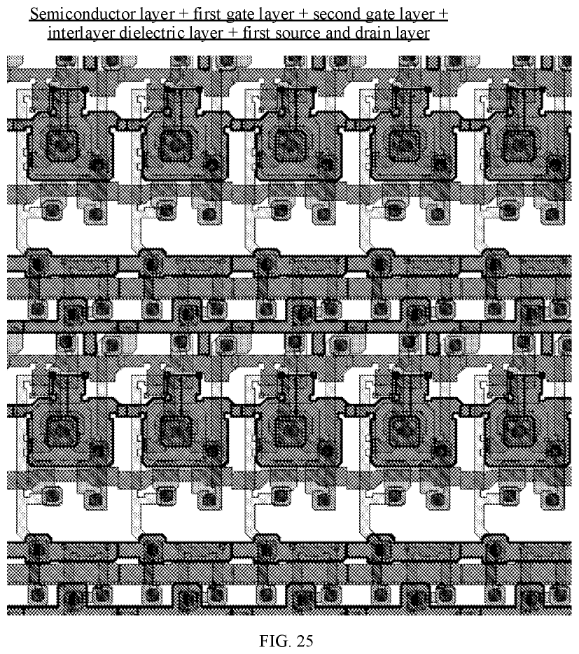

FIG. 24 is a locally schematic diagram of a first source and drain layer in a display panel according to some embodiments of the present disclosure. FIG. 25 is a locally schematic diagram of superposition of a semiconductor layer, a first gate layer, a second gate layer, an interlayer dielectric layer, and a first source and drain layer in a display panel according to some embodiments of the present disclosure. As shown in FIG. 24 and FIG. 25, the first source and drain layer includes a first connection structure h1, a second connection structure h2, a third connection structure h3, a fourth connection structure h4, a fifth connection structure h5, and a sixth connection structure h6. The first connection structure h1 is configured to connect the source (or the drain) of the threshold compensation transistor T2 and the gate of the drive transistor T3, the second connection structure h2 is configured to connect the second light-emitting control transistors T6, the third connection structure h3 is configured to connect the source (or the drain) of the third reset control transistor T7 and the reset power signal line g4, the fourth connection structure h4 is configured to connect the VDD signal line and the source (or the drain) of the first light-emitting control transistor T5, the fifth connection structure h5 is configured to connect the source (or the drain) of the data write transistor T4 and the data line g6, and the sixth connection structure h6 is configured to connect the second reset power signal lines g5.

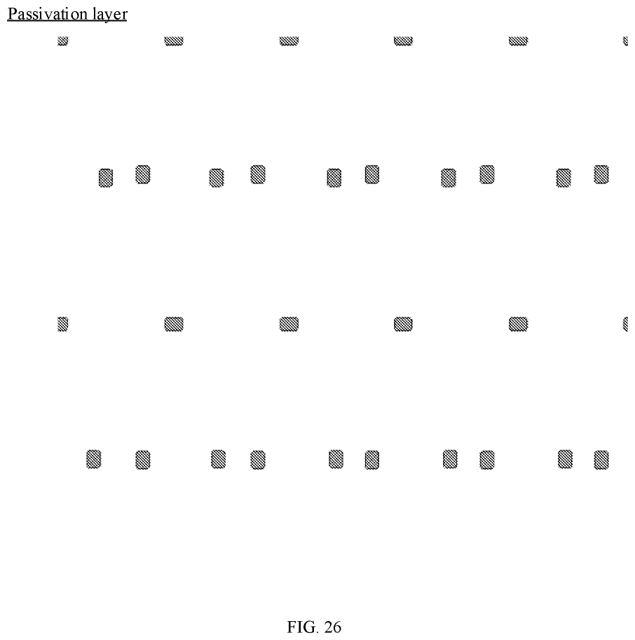

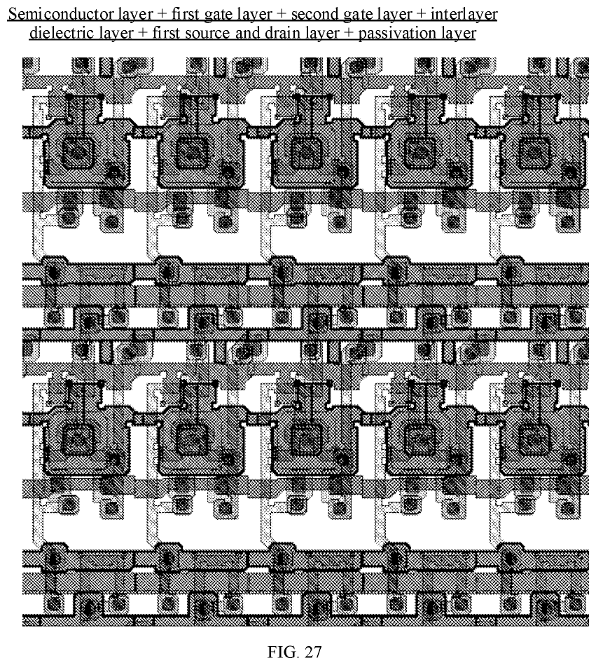

In addition, a passivation layer is formed on the above first source and drain layer, and is configured to insulate the above first source and drain layer from the subsequently formed intermediate source and drain layer. Referring to FIG. 26 and FIG. 27, for convenience of showing of vias in the passivation layer (PVX), filling patterns are used to represent the vias in FIG. 26 to FIG. 27, and other regions without filling patterns are used to represent regions of the passivation layer with real materials. It should be noted that the vias in the passivation layer are used to connect subsequently formed film layers and film layers on a side, proximal to the base substrate, of the passivation layer. That is, the vias are vias used to connect film layers.

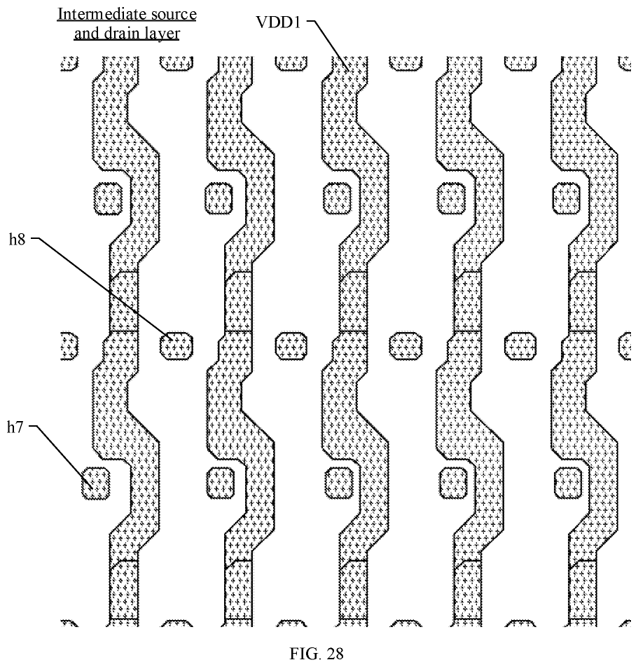

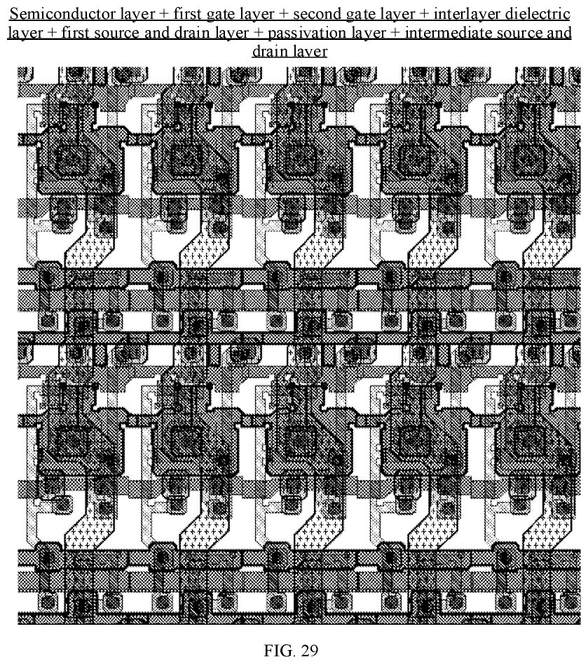

FIG. 28 is a locally schematic diagram of an intermediate source and drain layer in a display panel according to some embodiments of the present disclosure. FIG. 29 is a locally schematic diagram of superposition of a semiconductor layer, a first gate layer, a second gate layer, an interlayer dielectric layer, a first source and drain layer, a passivation layer, and an intermediate source and drain layer in a display panel according to some embodiments of the present disclosure. As shown in FIG. 28 and FIG. 29, the intermediate source and drain layer includes a first signal line VDD1, a seventh connection structure h7, and an eighth connection structure h8. The first signal line VDD1 is configured to be connected to the fourth connection structure h4, the seventh connection structure h7 is configured to be connected to the second connection structure h2, and the eighth connection structure h8 is configured to be connected to the fifth connection structure h5.

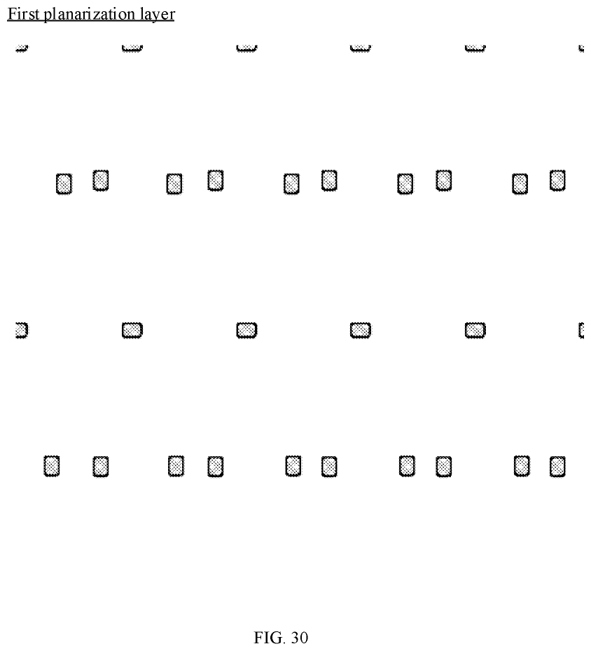

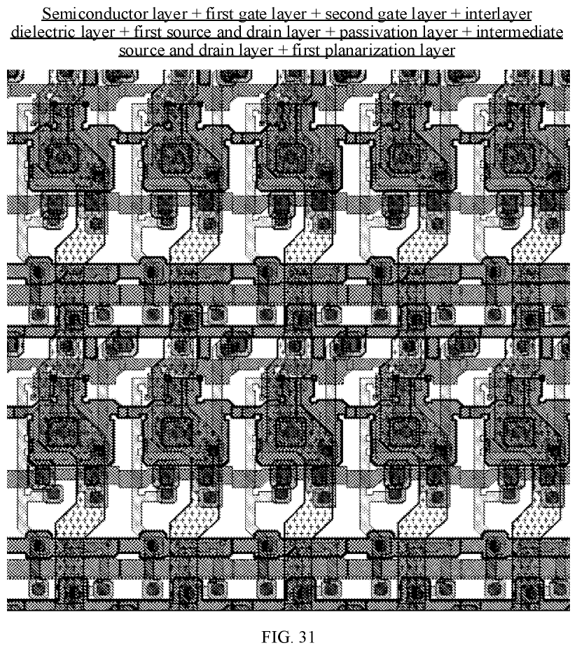

In addition, a first planarization layer (PLN1) is formed on the above intermediate source and drain layer, and is configured to insulate the above intermediate source and drain layer from the subsequently formed second source and drain layer. Referring to FIG. 30 and FIG. 31, for convenience of showing of vias in the first planarization layer, filling patterns are used to represent the vias in FIG. 30 to FIG. 31, and other regions without filling patterns are used to represent regions of the first planarization layer with real materials. It should be noted that the vias in the first planarization layer are used to connect subsequently formed film layers and film layers on a side, proximal to the base substrate, of the first planarization layer. That is, the vias are vias used to connect film layers.

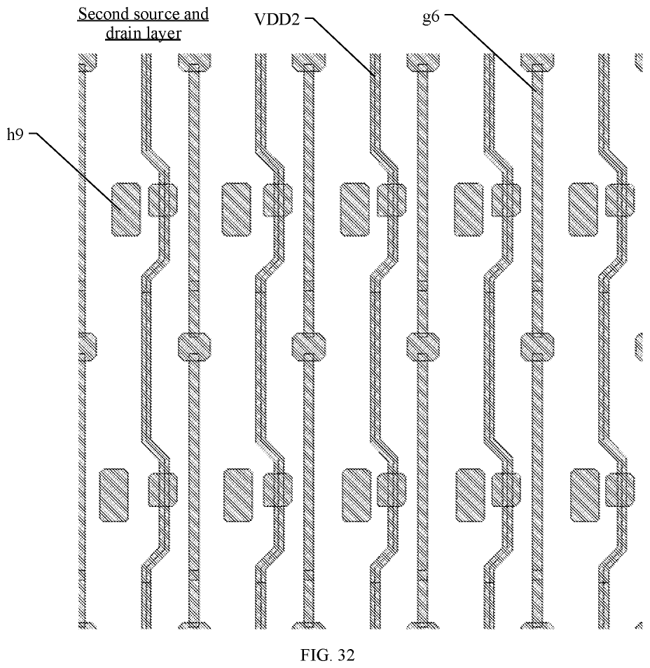

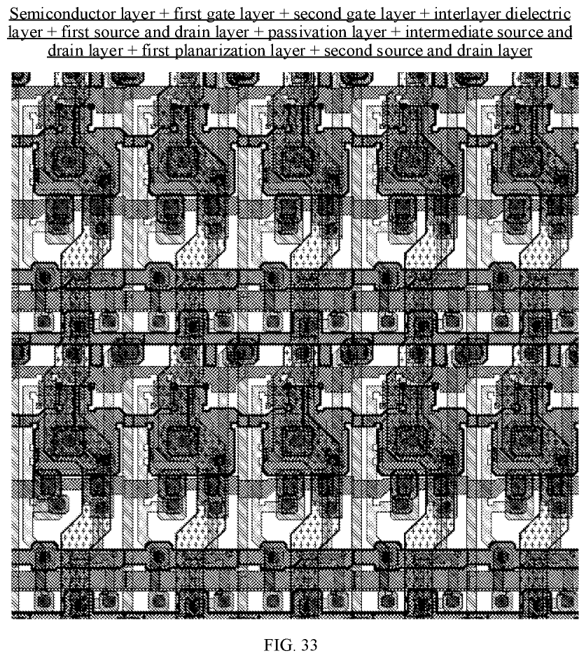

FIG. 32 is a locally schematic diagram of a second source and drain layer in a display panel according to some embodiments of the present disclosure. FIG. 33 is a locally schematic diagram of superposition of a semiconductor layer, a first gate layer, a second gate layer, an interlayer dielectric layer, a first source and drain layer, a passivation layer, an intermediate source and drain layer, a first planarization layer, and a second source and drain layer in a display panel according to some embodiments of the present disclosure. As shown in FIG. 32 and FIG. 33, the second source and drain layer includes a second signal line VDD2, data lines g6, and a ninth connection structure h9. The second signal line VDD2 is configured to be connected to the first signal line VDD1, the data line g6 is configured to be connected to the eighth connection structure h8, and the ninth connection structure h9 is configured to be connected to the seventh connection structure h7. Traces for transmitting the VDD signals includes the first signal line VDD1 and the second signal line VDD2.

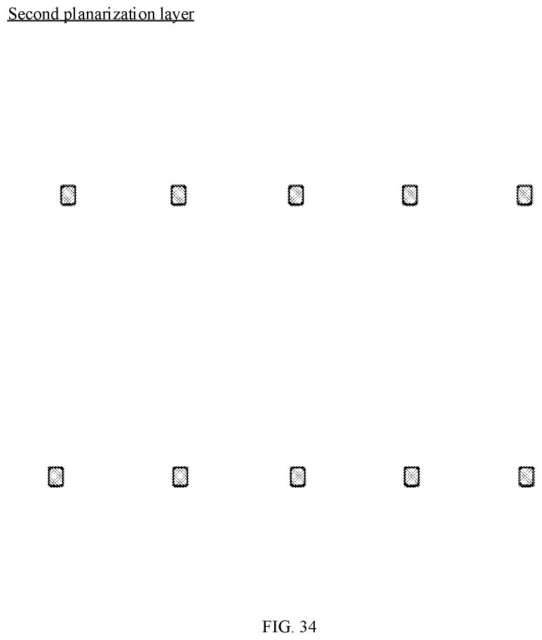

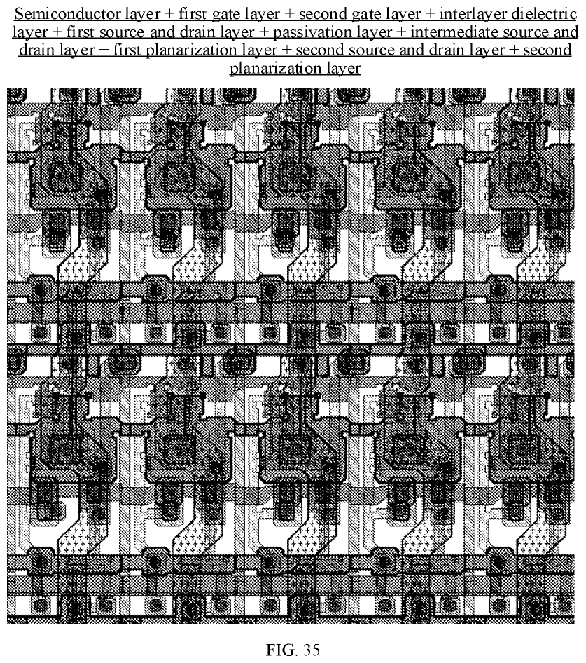

In addition, a second planarization layer (PLN2) is formed on the above second source and drain layer, and is configured to insulate the above second source and drain layer from the subsequently formed first conduction layer in the connection layer. Referring to FIG. 34 and FIG. 35, for convenience of showing of vias in the second planarization layer, filling patterns are used to represent the vias in FIG. 34 to FIG. 35, and other regions without filling patterns are used to represent regions of the second planarization layer with real materials. It should be noted that the vias in the second planarization layer are used to connect subsequently formed film layers and film layers on a side, proximal to the base substrate, of the second planarization layer. That is, the vias are vias used to connect film layers.

In summary, the embodiments of the present disclosure provide a display panel. As at least two first electrode patterns in the display panel are connected, and one of the at least two connected first electrode patterns is connected to one first pixel circuit, the one first pixel circuit drives the two first electrode patterns. As at least two second electrode patterns are connected, and one of the at least two connected second electrode patterns is connected to one second pixel circuit, the one second pixel circuit drives the two second electrode patterns. Thus, in the case that numbers of electrode patterns are the same, a number of pixel circuits in the second display region is reduced in driving two electrode patterns by one pixel circuit, such that a space of each pixel circuit is increased, and the process difficulty is less.

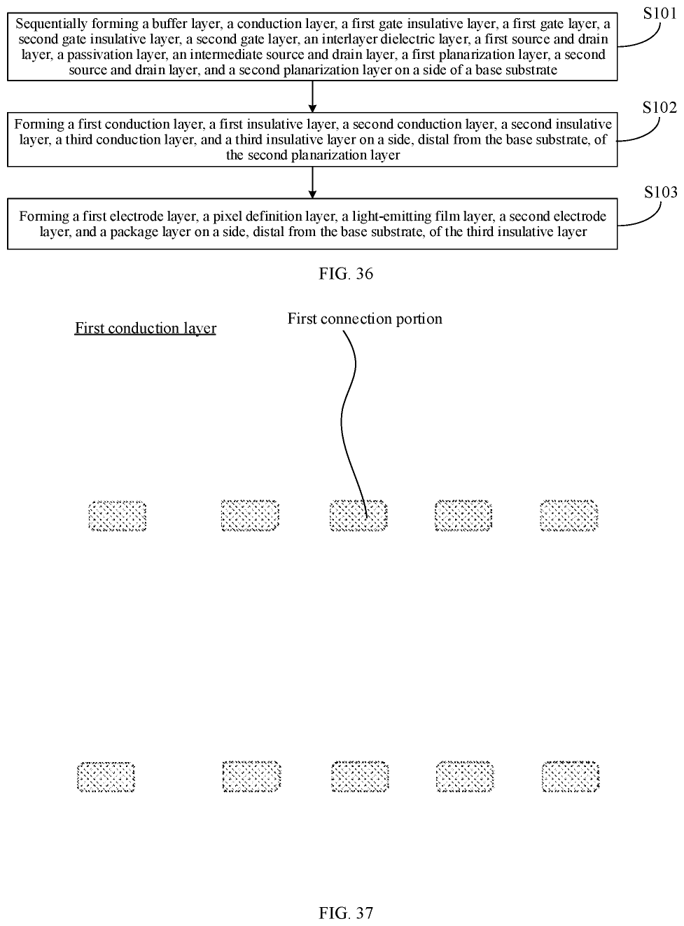

FIG. 36 is a flowchart of a method for manufacturing a display panel according to some embodiments of the present disclosure. The method is applicable to manufacturing the display panel in the above embodiments. Referring to FIG. 36, the method includes the following processes.

In S101, a buffer layer, a conduction layer, a first gate insulative layer, a first gate layer, a second gate insulative layer, a second gate layer, an interlayer dielectric layer, a first source and drain layer, a passivation layer, an intermediate source and drain layer, a first planarization layer, a second source and drain layer, and a second planarization layer are sequentially formed on a side of a base substrate.

In the embodiments of the present disclosure, in manufacturing the display panel, a base substrate is first acquired. The base substrate is a transparent glass substrate or a flexible substrate. Correspondingly, the acquired display substrate is a flexible display panel. The buffer layer and film layers in the drive circuit layer are formed on the side of the base substrate. The film layers in the drive circuit layer are referred to FIG. 17 to FIG. 35, which are not repeated herein.

In S102, a first conduction layer, a first insulative layer, a second conduction layer, a second insulative layer, a third conduction layer, and a third insulative layer are formed on a side, distal from the base substrate, of the second planarization layer.

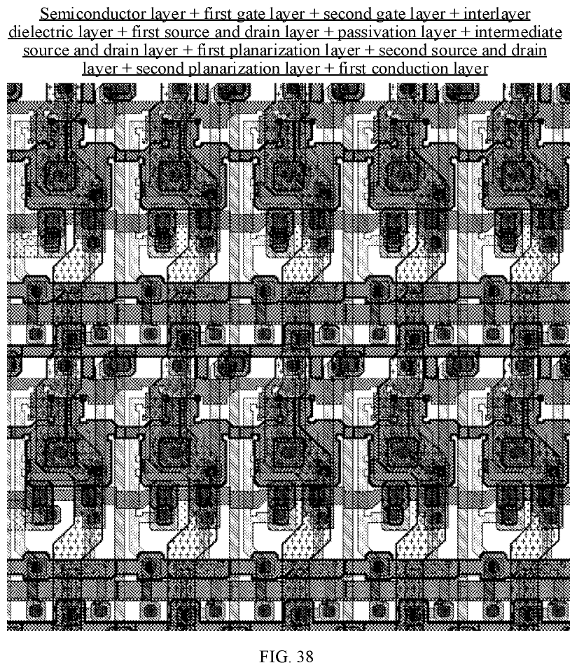

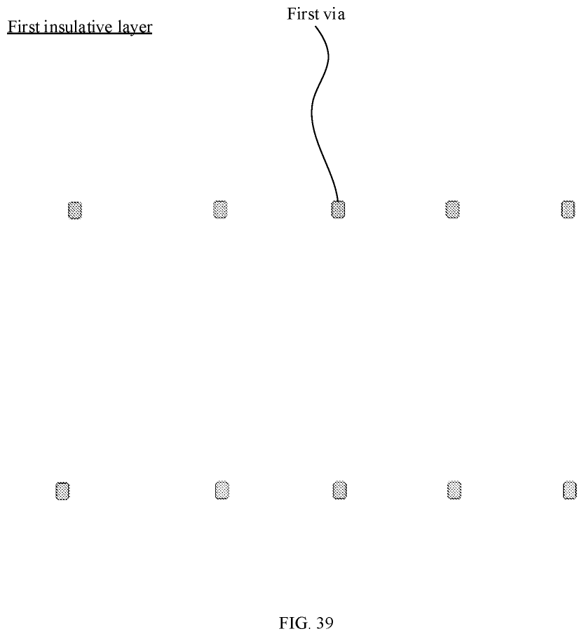

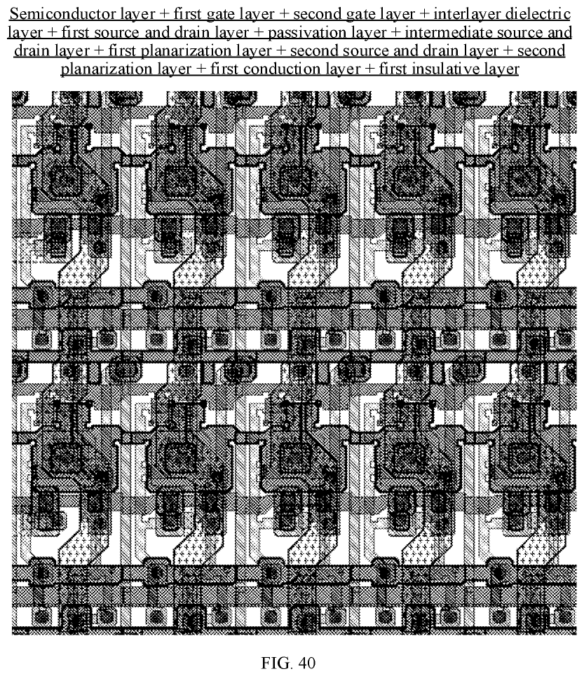

Referring to FIG. 37 and FIG. 38, the first conduction layer is formed on the side, distal from the base substrate, of the second planarization layer, and the first conduction layer includes a plurality of first connection portions. Referring to FIG. 39 and FIG. 40, a first insulative layer (a third planarization layer PLN3) is formed on a side, distal from the base substrate, of the first conduction layer. For convenience of showing of first vias in the first insulative layer, filling patterns are used to represent the first vias in FIG. 39 and FIG. 40, and other regions without filling patterns are used to represent regions of the first insulative layer with real materials. It should be noted that the first vias in the first insulative layer are used to connect subsequently formed film layers and film layers on a side, proximal to the base substrate, of the first insulative layer. That is, the first vias are vias used to connect film layers.

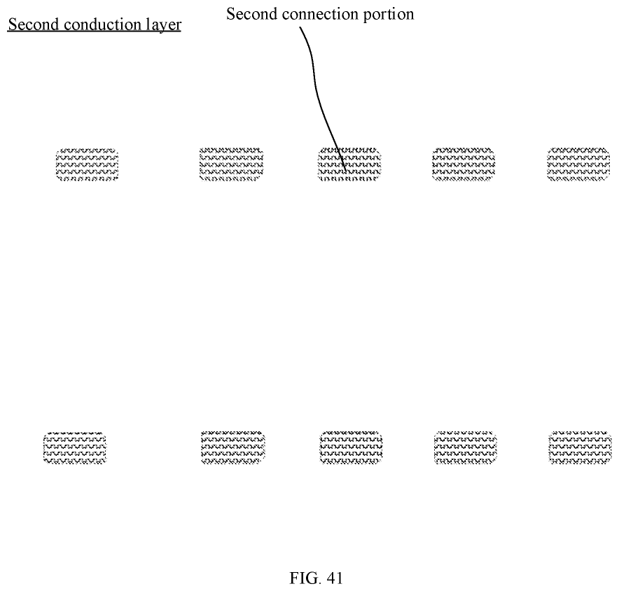

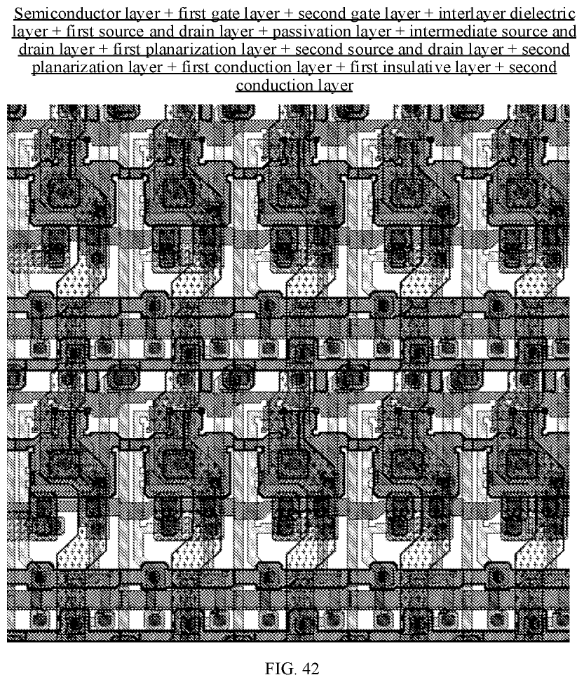

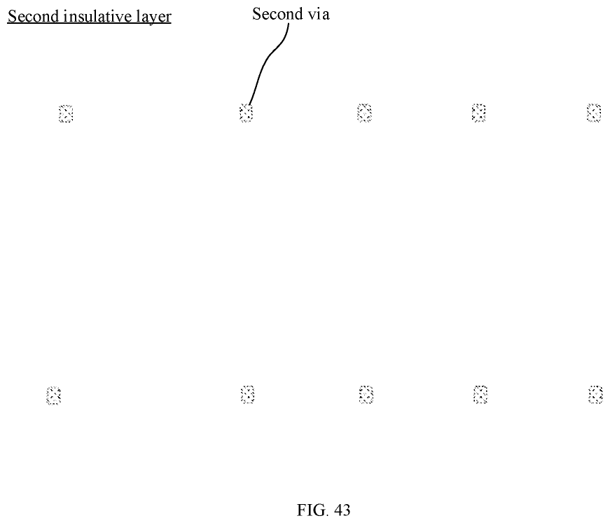

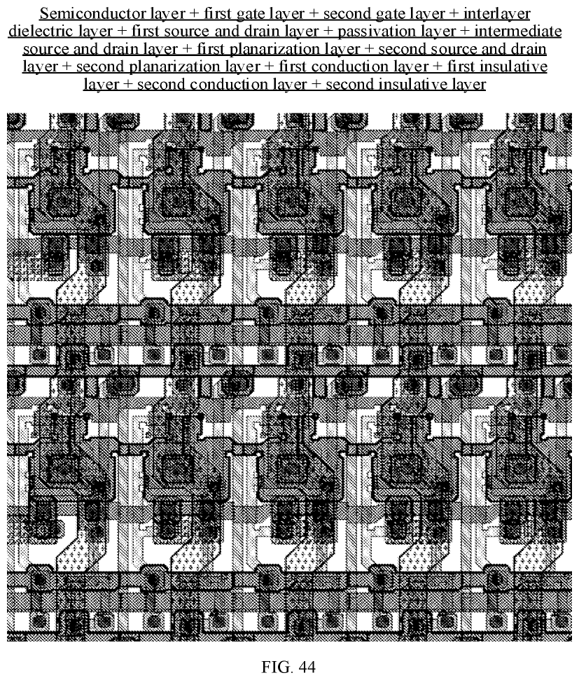

Referring to FIG. 41 and FIG. 42, the second conduction layer is formed on the side, distal from the base substrate, of the first insulative layer, and the second conduction layer includes a plurality of second connection portions. Referring to FIG. 43 and FIG. 44, a second insulative layer (a fourth planarization layer PLN4) is formed on a side, distal from the base substrate, of the second conduction layer. For convenience of showing of second vias in the second insulative layer, filling patterns are used to represent second vias in FIG. 43 and FIG. 44, and other regions without filling patterns are used to represent regions of the second insulative layer with real materials. It should be noted that the second vias in the second insulative layer are used to connect subsequently formed film layers and film layers on a side, proximal to the base substrate, of the second insulative layer. That is, the second vias are vias used to connect film layers.

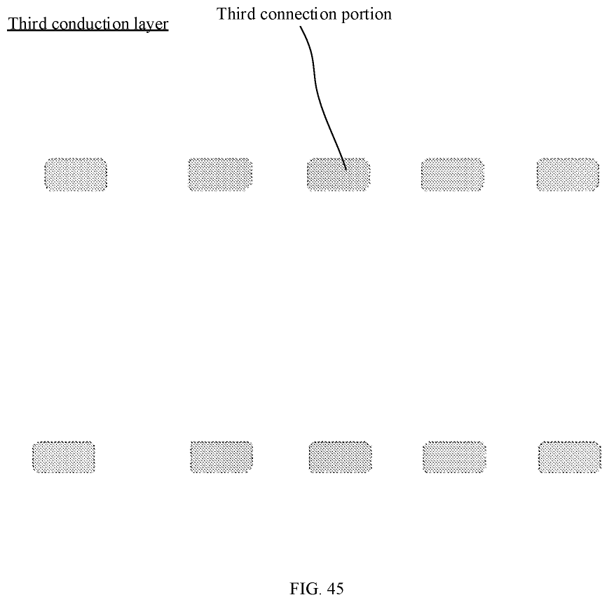

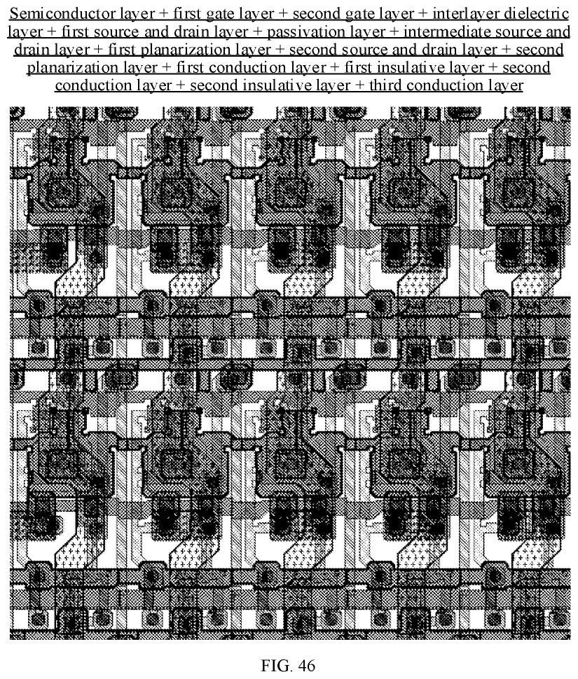

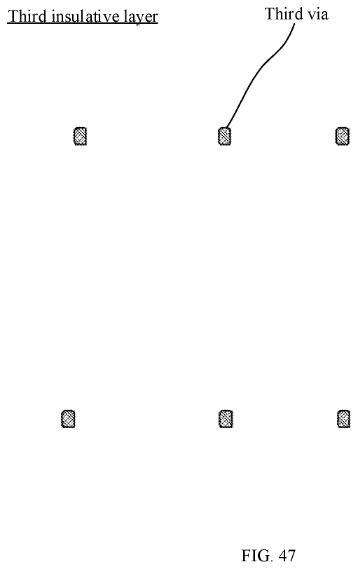

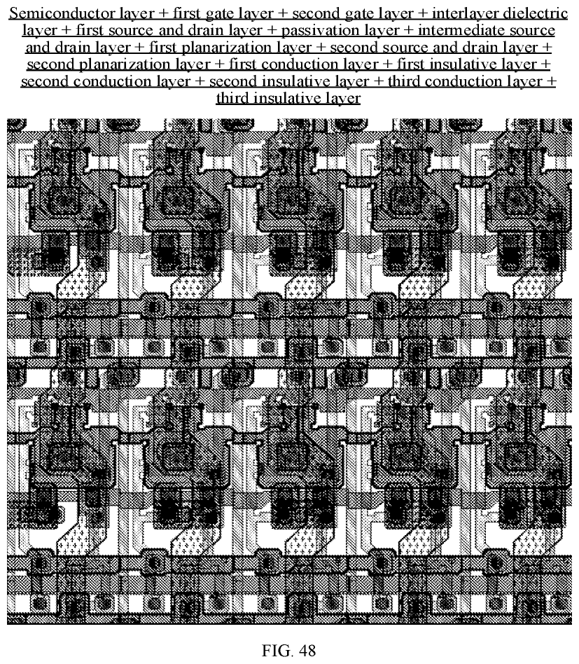

Referring to FIG. 45 and FIG. 46, the third conduction layer is formed on the side, distal from the base substrate, of the second insulative layer, and the third conduction layer includes a plurality of third connection portions. Referring to FIG. 47 and FIG. 48, a third insulative layer (a fifth planarization layer PLN5) is formed on a side, distal from the base substrate, of the third conduction layer. For convenience of showing of third vias in the third insulative layer, filling patterns are used to represent third vias in FIG. 47 and FIG. 48, and other regions without filling patterns are used to represent regions of the third insulative layer with real materials. It should be noted that the third vias in the third insulative layer are used to connect subsequently formed film layers and film layers on a side, proximal to the base substrate 101, of the third insulative layer. That is, the third vias are vias used to connect film layers.

In S103, a first electrode layer, a pixel definition layer, a light-emitting film layer, a second electrode layer, and a package layer are formed on a side, distal from the base substrate, of the third insulative layer.

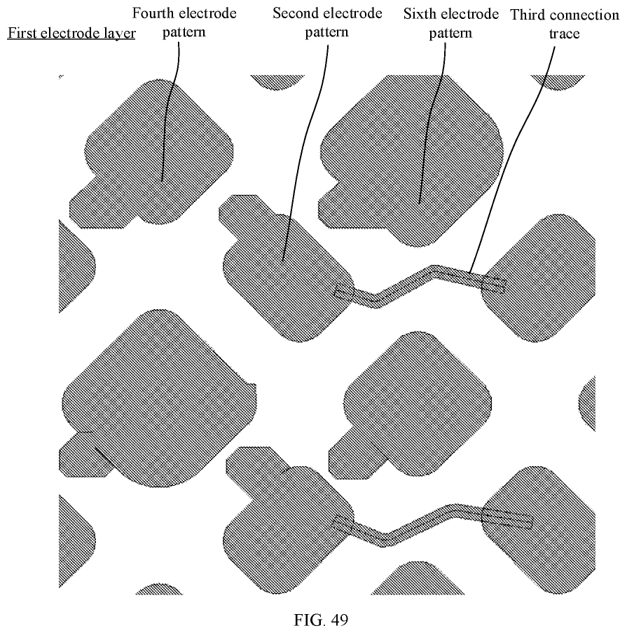

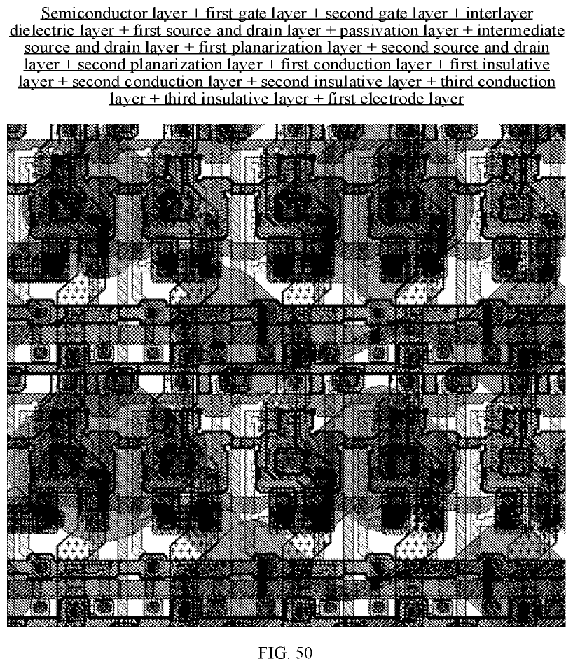

Referring to FIG. 49 and FIG. 50, the first electrode layer is formed on the side, distal from the base substrate, of the third insulative layer. The first electrode layer includes a plurality of electrode patterns, and each electrode pattern is determined as an anode of the pixel device. FIG. 49 and FIG. 50 show the second electrode patterns, the fourth electrode patterns, and the sixth electrode patterns.

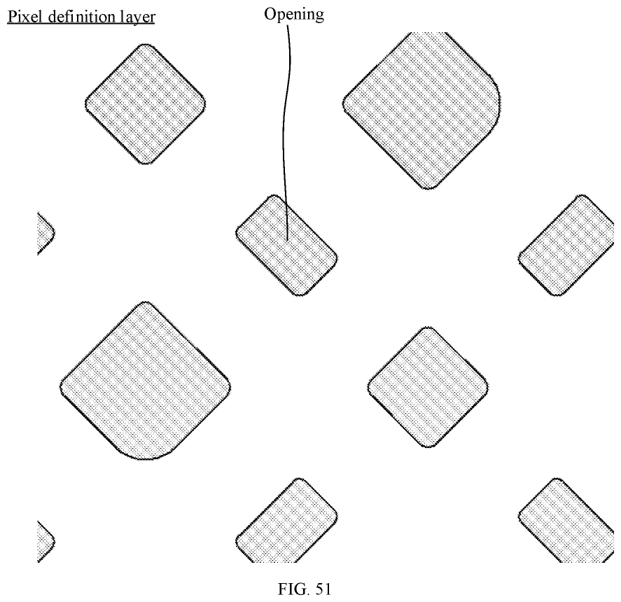

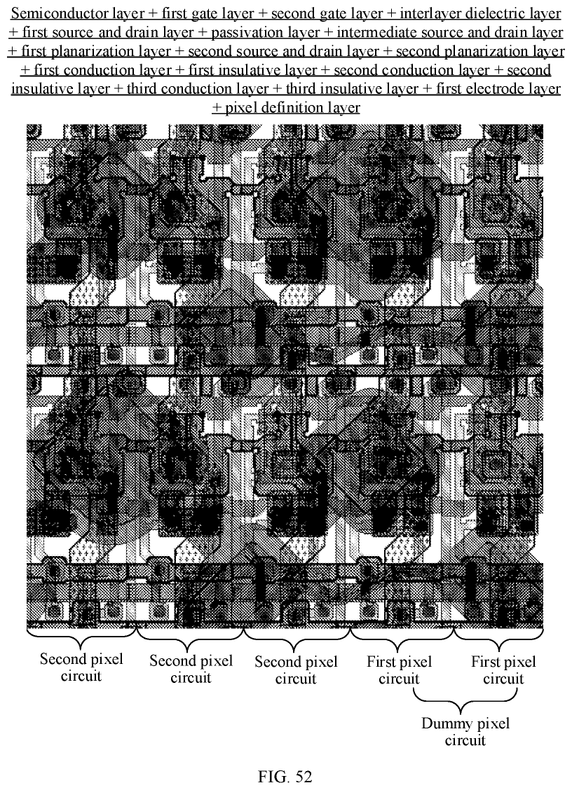

Referring to FIG. 51 and FIG. 52, the pixel definition layer is formed on a side, distal from the base substrate, of the first electrode layer. A plurality of openings are defined in the pixel definition layer, and each opening exposes one electrode pattern in the first electrode layer. For convenience of showing of the openings in the pixel definition layer, filling patterns are used to represent the openings in FIG. 51 and FIG. 52, and other regions without filling patterns are used to represent regions of the pixel definition layer with real materials. It should be noted that the openings in the pixel definition layer are used to connect subsequently formed film layers and film layers on a side, proximal to the base substrate, of the pixel definition layer. That is, the openings are openings used to cause the light-emitting layer in the light-emitting film layer to be in contact with the electrode patterns in the first electrode layer.

Upon formation of the pixel definition layer, the light-emitting film layer, the second electrode layer, and the package layer are sequentially formed on a side, distal from the base substrate, of the pixel definition layer, which are not described in detail in the embodiments of the present disclosure.

It should be noted that the method for manufacturing the display panel in the embodiments of the present disclosure is described by taking regions (the first display sub-region, the third display sub-region, the fourth display sub-region, the fifth display sub-region, and the sixth display sub-region) in the second display region other than the second display sub-region as an example. FIG. 17 to FIG. 51 are described by taking one circuit set A along the pixel row direction X and two circuit sets A in the pixel column direction Y as an example.

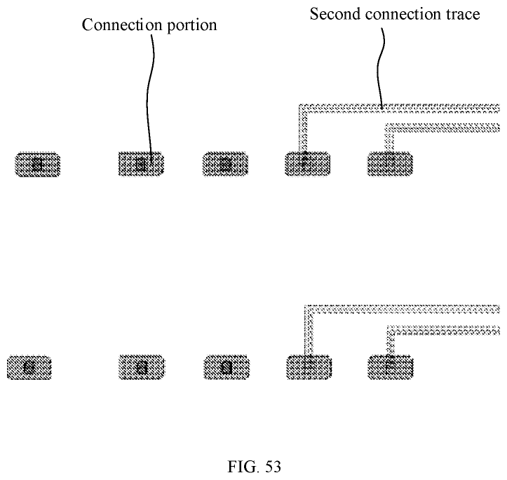

The second display sub-region (the transition display region) in the second display region and film layers in other regions in the second display region differ in the conduction layer. Referring to FIG. 53, a portion of the conduction layer in the second display sub-region includes a connection portion, a second connection trace, a fourth connection trace, or a fifth connection trace. That is, the portion of the conduction layer in the second display sub-region includes connection traces for connecting the pixel circuits in the second display sub-region and the electrode patterns in the first display region. The conduction layer in FIG. 53 is the first conduction layer, the second conduction layer, or the conduction layer. correspondingly, the connection portion in FIG. 53 is the first connection portion, the second connection portion, or the third connection portion.

In summary, the embodiments of the present disclosure provide a method for manufacturing a display panel. As at least two first electrode patterns in the acquired display panel are connected, and one of the at least two connected first electrode patterns is connected to one first pixel circuit, the one first pixel circuit drives the two first electrode patterns. As at least two second electrode patterns are connected, and one of the at least two connected second electrode patterns is connected to one second pixel circuit, the one second pixel circuit drives the two second electrode patterns. Thus, in the case that numbers of electrode patterns are the same, a number of pixel circuits in the second display region is reduced in driving two electrode patterns by one pixel circuit, such that a space of each pixel circuit is increased, and the process difficulty is less.

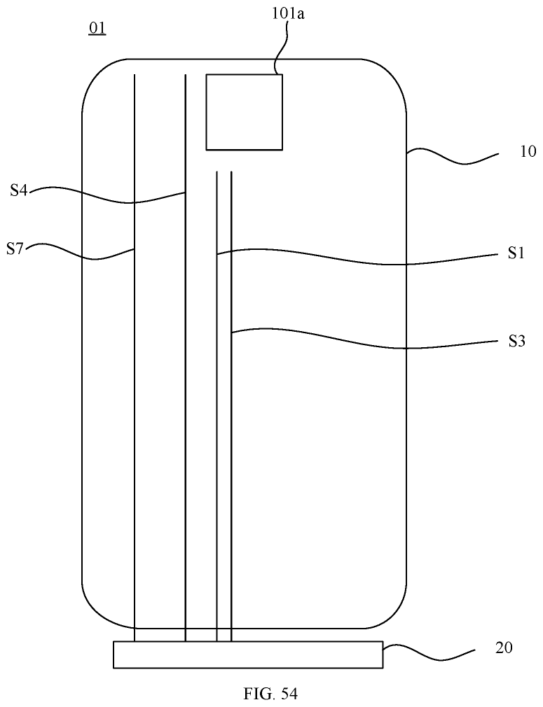

FIG. 54 is a schematic structural diagram of a display module according to some embodiments of the present disclosure. As shown in FIG. 54, the display module includes a data drive circuit 20 and the display panel 10 in the above embodiments. The data drive circuit 20 is connected to the first data lines S1, the third data lines S3, the fourth data lines S4, and the seventh data lines S7 in the display panel 10 to provide data drive signals to the first data lines S1, the third data lines S3, the fourth data lines S4, and the seventh data lines S7. One first data line S1, one third data line S3, one fourth data line S4, and one seventh data line S7 are illustratively shown in FIG. 54.

The second data line S2 is connected to the first data line S1 via the first patch code Z1, and the fifth data line S5 is connected to the second data line S2 via the second patch code Z2, such that the data drive circuit 20 provides the data drive signals to the second data line S2 and the fifth data line S5 via the first data line S1. The sixth data line S6 is connected to the fourth data line S4 via the third patch code Z3, such that the data drive circuit 20 provides the data drive signals to the sixth data line S6 via the fourth data line S4.

As the display module achieves the same technical effects as the display panel in the embodiments, the technical solutions of the display module are not repeated herein for concise.

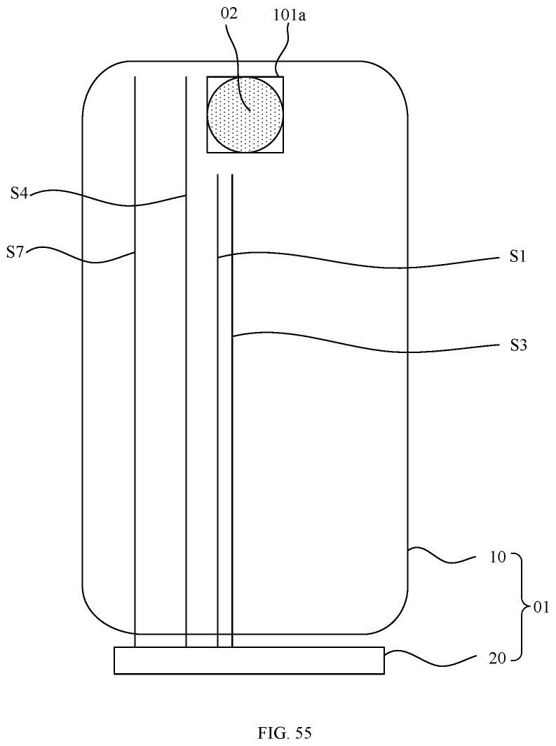

Referring to FIG. 55, the embodiments of the present disclosure provide a display device. The display device includes the display module 01 in the above embodiments and electrical elements such as the sensor 02, for example, an optical sensor 02. Illustratively, the display device is a mobile phone, the display device includes a front camera, a proximity optical sensor, a 3D sensing module, and other optical sensors, and the optical sensors require to receive light from a side of a display face of the display module 01 to achieve corresponding functions. In the display device, the optical sensor is generally disposed on a side of a non-display face of the display module 01, and a side of a light sensing face of the optical sensor faces towards the display module 01. An orthogonal projection of the optical sensor 02 on the display panel 10 is at least partially overlapped with the first display region 101a in the display panel.

In the embodiments of the present disclosure, the display device is an active-matrix organic light-emitting diode (AMOLED) display device, a passive-matrix organic light-emitting diode (PMOLED) display device, a quantum dot light emitting diodes (QLED) display device, an electronic paper, a mobile phone, a tablet computer, a television, a display, a notebook computer, a digital photo frame, a navigator, or any product or component with a display function.

As the display device achieves the same technical effects as the display panel in the embodiments, the technical solutions of the display device are not repeated herein for concise.

Terms in the embodiments of the present disclosure are used to explain the embodiments of the present disclosure, and are not intended to limit the present disclosure. Unless otherwise defined, the technical or scientific terms used in the embodiments of the present disclosure shall have ordinary meaning understood by persons of ordinary skill in the art to which the disclosure belongs. The terms “first,” “second,” “third,” and the like used in the embodiments of the present disclosure and claims are not intended to indicate any order, quantity or importance, but are merely used to distinguish different components. The terms “one” and “a” are not intended to indicate quantity limitation, and are intended to represent at least one. The terms “comprise” or “include” and the like are used to indicate that the element or object preceding the terms “comprise” or “include” covers the element or object following the terms “comprise” or “include” and its equivalents, and shall not be understood as excluding other elements or objects. The terms “connect” or “contact” and the like are not intended to be limited to physical or mechanical connections, but may include electrical connections, either direct or indirect connection. The terms “on,” “under,” “left,” and “right” are only used to indicate the relative positional relationship. When the absolute position of the described object changes, the relative positional relationship may change accordingly.

Described above are example embodiments of the present disclosure, and are not intended to limit the present disclosure. Any modifications, equivalent replacements, improvements and the like made within the spirit and principles of the present disclosure should be included within the scope of protection of the present disclosure.

1. A display panel, comprising:
a base substrate, comprising a first display region and a second display region at least partially surrounding the first display region;
a drive circuit layer on a side of the base substrate, wherein the drive circuit layer comprises a plurality of first pixel circuits and a plurality of second pixel circuits that are disposed in the second display region; and
a first electrode layer, at least comprising a plurality of first-type electrode patterns, wherein the plurality of first-type electrode patterns comprise a plurality of first electrode patterns in the first display region and a plurality of second electrode patterns in the second display region;
wherein at least two of the plurality of first electrode patterns are connected to one of the plurality of first pixel circuits, and at least two of the plurality of second electrode patterns are connected to one of the plurality of second pixel circuits.

2. The display panel according to claim 1, further comprising:
a plurality of first connection traces in the first display region;
a plurality of second connection traces extending from the second display region to the first display region along a pixel row direction;
a plurality of third connection traces in the second display region;
wherein at least two of the plurality of first electrode patterns are connected via one of the plurality of first connection traces, one of the at least two of the plurality of first electrode patterns is connected to one of the plurality of first pixel circuits via one of the plurality of second connection traces, at least two of the plurality of second electrode patterns are connected via one of the plurality of third connection traces, and one of the at least two of the plurality of second electrode patterns is connected to one of the plurality of second pixel circuits.

3. The display panel according to claim 2, further comprising: a plurality of fourth connection traces and a plurality of fifth connection traces that extend from the second display region to the first display region along the pixel row direction, and the first electrode layer further comprises a plurality of second-type electrode patterns and a plurality of third-type electrode patterns; wherein
the plurality of second-type electrode patterns comprise a plurality of third electrode patterns in the first display region and a plurality of fourth electrode patterns in the second display region, wherein each of the plurality of third electrode patterns is connected to one of the plurality of first pixel circuits via one of the plurality of fourth connection traces; and
the plurality of third-type electrode patterns comprise a plurality of fifth electrode patterns in the first display region and a plurality of sixth electrode patterns in the second display region, wherein each of the plurality of fifth electrode patterns is connected to one of the plurality of first pixel circuits via one of the plurality of fifth connection traces.

4. The display panel according to claim 3, wherein two of the plurality of first pixel circuits and three of the plurality of second pixel circuits that are adjacent form a circuit set, at least two of the plurality of second electrode patterns form an electrode pattern set, and one of the electrode pattern sets, one of the plurality of fourth electrode patterns, and one of the plurality of sixth electrode patterns that are adjacent form a pattern set,
wherein each of the pattern sets corresponds to one of the circuit sets, and for the each of the pattern sets and the corresponding circuit set, an orthogonal projection of the each of the pattern sets on the base substrate is overlapped with an orthogonal projection of the corresponding circuit set on the base substrate.

5. The display panel according to claim 4, wherein for each of the circuit sets and the pattern set corresponding to the each of the circuit sets, in three of the plurality of second pixel circuits in the each of the circuit sets, a first second pixel circuit in the three second pixel circuits is connected to one of the plurality of second electrode patterns in the electrode pattern set in the pattern set, a second second pixel circuit in the three second pixel circuits is connected to the fourth electrode pattern in the one pattern set, and a third second pixel circuit in the three second pixel circuits is connected to the sixth electrode pattern in the pattern set.

6. The display panel according to claim 4, wherein two of the plurality of first pixel circuits in one part of circuit sets in the display panel are connected to electrode patterns in the first display region, and two of the plurality of first pixel circuits in the other part of the circuit sets in the display panel are connected to a fixed voltage terminal.

7. The display panel according to claim 6, wherein the one part of circuit sets of the two of the plurality of first pixel circuits connected to the electrode patterns in the first display region are closer to the first display region than the other part of the circuit sets of the two of the plurality of first pixel circuits connected to the fixed voltage terminal are.

8. The display panel according to claim 3, further comprising: red sub-pixels, green sub-pixels, and blue sub-pixels, wherein sub-pixels of the plurality of first-type electrode patterns are the green sub-pixels, sub-pixels of the plurality of second-type electrode patterns are the red sub-pixels, and sub-pixels of the plurality of third-type electrode patterns are the blue sub-pixels.

9. The display panel according to claim 3, wherein a length of any of the plurality of second connection traces along the pixel row direction is less than a length of each of the plurality of fourth connection traces along the pixel row direction and a length of each of the plurality of fifth connection traces along the pixel row direction.

10. The display panel according to claim 3, wherein for each connection trace in the plurality of second connection traces, the plurality of fourth connection traces, and the plurality of fifth connection traces, a length of the each connection trace along the pixel row direction is positively correlated with a distance between the electrode pattern in the first display region connected to the each connection trace and the second display region along the pixel row direction.

11. The display panel according to claim 1, wherein
the second display region comprises a first display sub-region, a second display sub-region, and a third display sub-region, wherein the first display sub-region and the first display region are arranged along a pixel column direction, the second display sub-region and the first display region are arranged along the pixel row direction, the third display sub-region and the first display sub-region are arranged along the pixel row direction, and the third display sub-region and the second display sub-region are arranged in the pixel column direction; and
the display panel further comprises a plurality of first data lines in the first display sub-region, a plurality of second data lines in the second display sub-region and the third display sub-region, a plurality of first patch codes in the first display sub-region and the third display sub-region, wherein
the plurality of first data lines are arranged along the pixel row direction and extend in the pixel column direction, the plurality of second data lines are arranged along the pixel row direction and extend in the pixel column direction, and the plurality of first patch codes are arranged in the pixel column direction and extend along the pixel row direction; a first end of each of the plurality of first data lines is configured to be connected to a data drive circuit, a second end of the each of the plurality of first data lines is connected to a first end of one of the plurality of first patch codes, a second end of each of the plurality of first patch codes is connected to a first end of one of the plurality of second data lines; and the each of the plurality of first data lines is further connected to one column of the second pixel circuits configured to be connected to first target electrode patterns in the first display sub-region, and each of the plurality of second data lines is further connected to one column of the first pixel circuits configured to be connected to second target electrode patterns in the second display sub-region;
wherein the first target electrode patterns are at least one of the plurality of fourth electrode patterns and the plurality of sixth electrode patterns, and the second target electrode patterns are at least one of the plurality of third electrode patterns and the plurality of fifth electrode patterns.

12. The display panel according to claim 11, wherein the first target electrode patterns are the plurality of fourth electrode patterns or the plurality of sixth electrode patterns, the second target electrode patterns are the plurality of third electrode patterns or the plurality of fifth electrode patterns, and the display panel further comprises a plurality of third data lines in the first display sub-region, and a plurality of fourth data lines in the second display sub-region and the third display sub-region; wherein
the plurality of third data lines are arranged along the pixel row direction and extend in the pixel column direction, a first end of each of the plurality of third data lines is configured to be connected to the data drive circuit, and the each of the plurality of third data lines is further connected to one column of the second pixel circuits configured to be connected to the plurality of second electrode patterns in the first display sub-region; and
the plurality of fourth data lines are arranged along the pixel row direction and extend in the pixel column direction, a first end of each of the plurality of fourth data lines is configured to be connected to the data drive circuit, and the each of the plurality of fourth data lines is further connected to one column of the first pixel circuits configured to be connected to the plurality of first electrode patterns in the second display sub-region.

13. The display panel according to claim 11, wherein
the second display region further comprises a fourth display sub-region and a fifth display sub-region, wherein the fourth display sub-region is disposed on a side, distal from the first display sub-region, of the first display region, the fifth display sub-region and the fourth display sub-region are arranged along the pixel row direction, and the plurality of second data lines are disposed in the fifth display sub-region; and
the display panel further comprises a plurality of second patch codes and a plurality of fifth data lines in the fourth display sub-region, wherein the plurality of fifth data lines are arranged along the pixel row direction and extend in the pixel column direction, and the plurality of second patch codes are arranged in the pixel column direction and extend along the pixel row direction; a second end of the each of the plurality of second data lines is connected to a first end of one of the plurality of second patch codes, a second end of each of the plurality of second patch codes is connected to a first end of each of the plurality of fifth data lines, and each of the plurality of fifth data lines is further connected to one column of the second pixel circuits configured to be connected to the first target electrode patterns in the fourth display sub-region.

14. The display panel according to claim 11, further comprising: a plurality of first dummy data lines in the third display sub-region, wherein the plurality of first dummy data lines are arranged along the pixel row direction and extend in the pixel column direction, configured to be connected to a fixed voltage terminal, and further connected to one column of the first pixel circuits in the third display sub-region.

15. The display panel according to claim 1, wherein
the second display region further comprises a sixth display sub-region on a side, distal from the first display sub-region, of the third display sub-region; and
the display panel further comprises a plurality of seventh data lines in the sixth display sub-region and a plurality of second dummy data lines in the sixth display sub-region; wherein
the plurality of seventh data lines are arranged along the pixel row direction and extend in the pixel column direction, and each of the plurality of seventh data lines is configured to be connected to a data drive circuit and further connected to one column of the second pixel circuits in the sixth display sub-region; and
the plurality of second dummy data lines are arranged along the pixel row direction and extend in the pixel column direction, each of the plurality of second dummy data lines is configured to be connected to a fixed voltage terminal, and the plurality of second dummy data lines are further connected to one column of the first pixel circuits in the sixth display sub-region.

16. The display panel according to claim 2, wherein the plurality of third connection traces and the first electrode layer are disposed in a same layer, and the plurality of first connection traces and the plurality of second connection traces are disposed between the drive circuit layer and the first electrode layer.

17. A display module, comprising: a data drive circuit and a display panel; wherein
the display panel includes:
a base substrate, comprising a first display region and a second display region at least partially surrounding the first display region;
a drive circuit layer on a side of the base substrate, wherein the drive circuit layer comprises a plurality of first pixel circuits and a plurality of second pixel circuits that are disposed in the second display region; and
a first electrode layer, at least comprising a plurality of first-type electrode patterns, wherein the plurality of first-type electrode patterns comprise a plurality of first electrode patterns in the first display region and a plurality of second electrode patterns in the second display region;
wherein at least two of the plurality of first electrode patterns are connected to one of the plurality of first pixel circuits, and at least two of the plurality of second electrode patterns are connected to one of the plurality of second pixel circuits; and
the data drive circuit is connected to first data lines, third data lines, fourth data lines, and seventh data lines that are in the display panel.

18. A display device, comprising: a display module and an optical sensor, wherein
the display module a data drive circuit and a display panel; wherein the display panel includes: a base substrate, comprising a first display region and a second display region at least partially surrounding the first display region; a drive circuit layer on a side of the base substrate, wherein the drive circuit layer comprises a plurality of first pixel circuits and a plurality of second pixel circuits that are disposed in the second display region; and a first electrode layer, at least comprising a plurality of first-type electrode patterns, wherein the plurality of first-type electrode patterns comprise a plurality of first electrode patterns in the first display region and a plurality of second electrode patterns in the second display region; wherein at least two of the plurality of first electrode patterns are connected to one of the plurality of first pixel circuits, and at least two of the plurality of second electrode patterns are connected to one of the plurality of second pixel circuits; and
an orthogonal projection of the optical sensor on the display panel is at least partially overlapped with the first display region in the display panel.

19. The display module according to claim 17, wherein the display panel further comprises:
a plurality of first connection traces in the first display region;
a plurality of second connection traces extending from the second display region to the first display region along a pixel row direction;
a plurality of third connection traces in the second display region;
wherein at least two of the plurality of first electrode patterns are connected via one of the plurality of first connection traces, one of the at least two of the plurality of first electrode patterns is connected to one of the plurality of first pixel circuits via one of the plurality of second connection traces, at least two of the plurality of second electrode patterns are connected via one of the plurality of third connection traces, and one of the at least two of the plurality of second electrode patterns is connected to one of the plurality of second pixel circuits.

20. The display module according to claim 19, wherein the display panel further comprises: a plurality of fourth connection traces and a plurality of fifth connection traces that extend from the second display region to the first display region along the pixel row direction, and the first electrode layer further comprises a plurality of second-type electrode patterns and a plurality of third-type electrode patterns; wherein
the plurality of second-type electrode patterns comprise a plurality of third electrode patterns in the first display region and a plurality of fourth electrode patterns in the second display region, wherein each of the plurality of third electrode patterns is connected to one of the plurality of first pixel circuits via one of the plurality of fourth connection traces; and
the plurality of third-type electrode patterns comprise a plurality of fifth electrode patterns in the first display region and a plurality of sixth electrode patterns in the second display region, wherein each of the plurality of fifth electrode patterns is connected to one of the plurality of first pixel circuits via one of the plurality of fifth connection traces.
